(19) United States
(12) Patent Application Publication
(10) Pub. No.: US 2025/0179680 A1
(43) Pub. Date: Jun. 5, 2025

(54) GAP CHARACTERIZATION IN ELECTRODEPOSITION TOOL

(71) Applicant: Lam Research Corporation, Fremont, CA (US)

(72) Inventors: Jared HERR, Tigard, OR (US); Jacob L. HIESTER, Newberg, OR (US); Chad M. HOSACK, Newberg, OR (US); Gabriel GRAHAM, Portland, OR (US); Marc QUAGLIO, Sherwood, OR (US); Robert RASH, West Linn, OR (US); James FORTNER, Newberg, OR (US); Jason Gordon GALGINAITIS, Portland, OR (US); Kevin BERTSCH, Tigard, OR (US)

(21) Appl. No.: 18/842,362

(22) PCT Filed: Feb. 28, 2023
(86) PCT No.: PCT/US2023/063390

§ 371 Date: Aug. 28, 2024

Related U.S. Application Data
(60) Provisional application No. 63/268,746, filed on Mar. 1, 2022.
(60) Provisional application No. 63/269,035, filed on Mar. 8, 2022.

(51) Int. Cl. C25D 17/00; C25D 17/06; C25D 21/12

(52) U.S. Cl. CPC C25D 17/001; C25D 17/06; C25D 21/12

(57) ABSTRACT

Examples are disclosed herein that relate to characterizing a plating gap between an anode structure and a cathode in an electrodeposition tool. One example provides a fixture for characterizing a spacing of a plating gap of an electrodeposition tool. The fixture comprises a substrate holder interface configured to contact a seal of a substrate holder of the electrodeposition tool. The fixture further comprises a protrusion comprising a contact surface configured to contact the anode structure of the electrodeposition tool during a plating gap characterization process. A thickness dimension comprising a distance between a plane of the substrate holder interface and the contact surface of the protrusion corresponds to a preselected plating gap spacing.

### BACKGROUND

Electrodeposition can be used in integrated circuit manufacturing processes to deposit electrically conductive films onto substrates. Electrodeposition involves the electrochemical reduction of dissolved ions of a selected metal to an elemental state on the substrate surface, thereby forming a film of the selected metal on the substrate.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed herein that relate to characterizing a plating gap between an anode structure and a cathode in an electrodeposition tool. One example provides a fixture for characterizing a spacing of a plating gap of an electrodeposition tool. The fixture comprises a substrate holder interface configured to contact a seal of a substrate holder of the electrodeposition tool. The fixture further comprises a protrusion comprising a contact surface configured to contact the anode structure of the electrodeposition tool during a plating gap characterization process. A thickness dimension of the fixture comprising a distance between a plane of the substrate holder interface and the contact surface of the protrusion corresponds to a preselected plating gap spacing.

In some such examples, the fixture is formed at least in part from a polymer.

In some such examples, the fixture is formed at least in part from a metal.

In some such examples, the protrusion comprises a curvature comprising a radius within a range of 0.5 inch and 1.5 inch.

In some such examples, the protrusion is offset from a rotational center of the fixture.

In some such examples, a center of mass of the fixture is located at the rotational center of the fixture.

In some such examples, the substrate holder interface comprises a thinner profile than an adjacent region of the fixture.

In some such examples, the fixture additionally or alternatively comprises one or more angular alignment features.

Another example provides an electrodeposition system. The electrodeposition system comprises a plating cell comprising an anode structure, a substrate holder, a lift configured to change a spacing between the anode structure and the substrate holder, a motor configured to rotate the substrate holder, and a controller configured to characterize a plating gap of the electrodeposition system. The controller comprises instructions executable to actuate the lift to move the substrate holder relative to the anode structure while a gap characterization fixture is held in the substrate holder, apply a rotational torque to the substrate holder, detect a lift position at which the substrate holder meets a threshold rotational condition, and output a gap characterization measurement based upon the lift position at which the substrate holder met the threshold rotational condition.

In some such examples, the controller comprises instructions executable to output a gap characterization measurement for each of a plurality of rotation angles of the substrate holder.

In some such examples, the controller additionally or alternatively comprises instructions executable to detect the lift position at which the substrate holder meets the threshold rotational condition by actuating the lift to move the substrate holder toward the anode structure until a hard touch is detected between the anode structure and a gap characterization fixture held in the substrate holder, and while the rotational torque is applied, actuate the lift to move the substrate holder away from the anode structure.

In some such examples, the plating cell the instructions are additionally or alternatively executable to detect the hard touch by detecting a threshold torque applied by the lift.

In some such examples, the plating cell is located in a substrate processing station, and the electrodeposition system further comprises a maintenance fixture storage system configured to hold one or more maintenance fixtures, and a robot system controllable by the controller to transfer a maintenance fixture from the maintenance fixture storage system to a substrate processing station of the one or more substrate processing stations.

In some such examples, the maintenance fixture storage system alternatively or additionally comprises one or more maintenance fixture storage locations and one or more presence sensors each configured to detect a presence of a maintenance fixture stored in a respective fixture storage location, and wherein the controller is configured to receive presence data from the one or more presence sensors of the maintenance fixture storage system, and display information on a presence or absence of the maintenance fixture on a user interface displayed on a display device.

In some such examples, the plating cell alternatively or additionally is a first plating cell, the substrate holder is a first substrate holder, and the electrodeposition system comprises a second plating cell and a second substrate holder coupled with the lift. In such examples, the controller additionally or alternatively further comprises instructions executable to apply a rotational torque to the second substrate holder after the hard touch is detected and before the lift is actuated, and outputs an error notification when the second substrate holder does not rotate in response.

In some such examples, the electrodeposition system additionally or alternatively comprises a plurality of leveling adjusters, and wherein the controller further comprises instructions executable to automatically adjust one or more of the leveling adjusters based upon the gap characterization measurement.

Another example provides an electrodeposition system. The electrodeposition system comprises a plating cell comprising an anode structure, a substrate holder, a lift configured to change a spacing between the plating cell and the substrate holder, a display, and a computing device comprising a logic subsystem and a storage subsystem. The storage subsystem comprises instructions executable by the logic subsystem to actuate the lift to move the substrate holder toward the anode structure until a hard touch between the anode structure and a gap characterization fixture in the substrate holder is detected. The storage system further comprises instructions executable to apply a rotational torque to the substrate holder, and while the rotational torque is applied, actuate the lift to move the substrate holder away from the anode structure. The storage system further comprises instructions executable to detect a lift position at which the substrate holder begins to rotate, output a gap characterization measurement based upon the lift position at which the substrate holder began to rotate, and display the gap characterization measurement on a user interface via the display.

In some such examples, the instructions are additionally or alternatively executable to output a gap characterization measurement for each of a plurality of rotation angles of the substrate holder, and display on the user interface a cell parallelism measurement characterizing an alignment of the plating cell to the substrate holder.

In some such examples, the instructions are additionally or alternatively executable to receive a user input of a cell parallelism threshold, compare the cell parallelism measurement to the cell parallelism threshold, and output a notification if the cell parallelism measurement exceeds the cell parallelism threshold.

In some such examples, the instructions are additionally or alternatively executable to display a representation of an adjustment to be made to one or more leveling adjusters based on the plurality of gap characterization measurements.

In some such examples, the instructions are additionally or alternatively executable to automatically adjust one or more leveling adjusters based on the plurality of gap characterization measurements.

In some such examples, the instructions are additionally or alternatively executable to display on the user interface, for a plurality of gap characterization measurements each made at a corresponding rotation angle of the substrate holder, one or more of an average gap measurement, a minimum gap measurement, or a maximum gap measurement.

Examples also are disclosed that relate to storing and handling maintenance fixtures for use with semiconductor processing tools. One example provides a substrate processing tool. The substrate processing tool comprises a substrate processing module comprising one or more substrate processing stations. The substrate processing tool further comprises a maintenance fixture storage system positioned within the substrate processing module. The maintenance fixture storage system is configured to hold one or more maintenance fixtures. The substrate processing tool further comprises a controller and a robot system controllable by the controller to transfer a maintenance fixture from the maintenance fixture storage system to a substrate processing station of the one or more substrate processing stations.

In some examples, the one or more substrate processing stations comprises one or more electrodeposition stations.

In some examples, the one or more maintenance fixtures additionally or alternatively comprises one or more auto debubble fixtures.

In some such examples, the one or more maintenance fixtures additionally or alternatively comprises one or more auto plating gap characterization fixtures.

In some such examples, each substrate processing station of the one or more substrate processing stations additionally or alternatively comprises two or more electrodeposition cells, and the one or more maintenance fixtures further comprises one or more companion fixtures for each auto plating gap characterization fixture.

In some such examples, the robot system additionally or alternatively is configured to transfer substrates and a maintenance fixture with a same robot.

In some such examples, the maintenance fixture storage system additionally or alternatively further comprises an installation sensor configured to detect whether the maintenance fixture storage system is installed within the substrate processing module.

In some such examples, the maintenance fixture storage system additionally or alternatively comprises one or more fixture storage locations configured to store the one or more maintenance fixtures.

In some such examples, the maintenance fixture storage system additionally or alternatively further comprises one or more presence sensors, each configured to detect a presence of a maintenance fixture stored in a respective fixture storage location.

Another example provides a maintenance fixture storage system configured for use with a substrate processing tool. The maintenance fixture storage system comprises one or more maintenance fixture storage locations, each maintenance fixture storage location configured to hold a maintenance fixture for a substrate processing tool. The maintenance fixture storage system further comprises one or more presence sensors each configured to detect presence of a maintenance fixture stored in a corresponding maintenance fixture storage location. The maintenance fixture storage system further comprises one or more mounting features configured for mounting the maintenance fixture storage system within a substrate processing module.

In some such examples, the one or more presence sensors comprises one or more of an optical sensor, a mechanical switch, a capacitive sensor, an inductive sensor, a radiofrequency identification sensor, or a near-field communication sensor.

In some such examples, the maintenance fixture storage system additionally or alternatively further comprises an angular alignment feature located within a maintenance fixture storage location of the one or more maintenance fixture storage locations, the angular alignment feature configured to align with a corresponding angular alignment feature of a maintenance fixture.

In some such examples, the one or more presence sensors additionally or alternatively are each further configured to output a signal indicating an absence of a maintenance fixture in a corresponding fixture storage location when the angular alignment feature of the fixture storage location and the corresponding angular alignment feature of the maintenance fixture are not aligned.

In some such examples, the maintenance fixture storage system additionally or alternatively further comprises an installation sensor configured to output a signal indicating that the maintenance fixture storage system is installed correctly in the substrate processing tool.

In some such examples, the maintenance fixture storage system additionally or alternatively further comprises a kinematic mounting system.

Another example provides a method of performing a maintenance cycle within a substrate processing tool. The method comprises controlling a robot system to remove a maintenance fixture from a maintenance fixture storage system located within a substrate processing module of the processing tool. The method further comprises controlling the robot system to place the maintenance fixture into a substrate processing station of the substrate processing module. The method further comprises controlling the substrate processing station to perform a maintenance cycle using the maintenance fixture.

In some such examples, the method further comprises receiving a signal from a presence sensor indicating removal of a maintenance fixture from the maintenance fixture storage system.

In some such examples, the method additionally or alternatively further comprises controlling the robot system to remove the maintenance fixture from the substrate processing station after performing the maintenance cycle.

In some such examples, the method additionally or alternatively further comprises controlling the robot system to place the maintenance fixture into a rinsing station of the substrate processing module after removing the maintenance fixture from the substrate processing station.

In some such examples, the maintenance fixture comprises an angular alignment feature and the maintenance fixture storage system comprises a corresponding angular alignment feature, and the method additionally or alternatively further comprises controlling the robot system to place the maintenance fixture into the maintenance fixture storage system with the angular alignment feature aligned with the corresponding angular alignment feature.

Another example provides a computing device. The computing device comprises one or more processors and one or more storage devices storing instructions executable by the one or more processors to present a user interface for a maintenance fixture storage system of a substrate processing tool. The instructions comprise instructions executable to receive presence data from one or more presence sensors of the maintenance fixture storage system, each presence sensor configured to output a signal indicative of whether a maintenance fixture is positioned within a maintenance fixture storage location of the maintenance fixture storage system. The instructions further comprise instructions executable to display information on a presence or absence of the maintenance fixture on the user interface.

In some such examples, the maintenance fixture storage system comprises a plurality of maintenance fixture storage locations, and the instructions are executable to display information regarding whether each maintenance fixture storage location is occupied by a maintenance fixture.

In some such examples, the instructions additionally or alternatively are executable to display, on the user interface, information regarding a type of maintenance fixture in each of the plurality of maintenance fixture storage locations.

In some such examples, the instructions additionally or alternatively are executable to display, on the user interface, information regarding a compatibility of each maintenance fixture with a substrate processing station of a plurality of substrate processing stations.

In some such examples, the computing device additionally or alternatively is incorporated in the substrate processing tool.

In some such examples, the instructions additionally or alternatively are further executable to display, on the user interface, information regarding a usage count for the maintenance fixture.

In some such examples, the instructions additionally or alternatively are further executable to display on the user interface information regarding whether the maintenance fixture storage system is installed in the substrate processing tool based upon a signal from an installation sensor.

In some such examples, the instructions additionally or alternatively are further executable to receive a user input comprising information regarding a selected maintenance routine to be performed using the maintenance fixture.

In some such examples, the instructions additionally or alternatively are further executable to display a status indication of the selected maintenance routine on the user interface.

### BRIEF DESCRIPTION OF THE DRAWINGS

FIG. 1 shows a block diagram of an example electrodeposition tool.

FIG. 2 shows a schematic sectional view of an example substrate holder for an electrodeposition tool.

FIG. 3 schematically shows a gap between a substrate and an anode structure.

FIG. 4 shows an example gap characterization fixture.

FIG. 5 shows another example gap characterization fixture.

FIG. 6 schematically shows another example gap characterization fixture, and a portion of a substrate holder in which the fixture is positioned.

FIG. 7 shows a flow diagram depicting an example method for characterizing a plating gap in an electrodeposition tool.

FIG. 8 shows a flow diagram depicting an example method for performing a gap characterization measurement for an electrodeposition tool.

FIG. 9 schematically shows various stages in an example process for performing gap characterization measurements for two plating cells.

FIG. 10 shows a graph of a measured height of an anode structure versus an angle of a substrate holder as determined by gap characterization, and also shows a schematic representation of angles at which measurements were taken.

FIG. 11 shows an example computing device user interface for an electrodeposition system configured to perform gap characterization.

FIGS. 12A and 12B show a flow diagram depicting an example method for operating an electrodeposition system to perform gap characterization.

FIG. 13 schematically shows an example substrate processing tool including a maintenance fixture storage and handling system.

FIGS. 14A-14C schematically show an example maintenance fixture storage system, and an alignment feature within a maintenance storage fixture location of the storage system.

FIG. 15 shows an example user interface that provides status and control information for a maintenance fixture storage system.

FIGS. 16A-16B show a flow diagram illustrating an example method for performing a maintenance cycle within a substrate processing tool.

FIG. 17 shows an example method for displaying information regarding a substrate processing tool on a user interface.

FIG. 18 shows a block diagram of an example computing system.

### DETAILED DESCRIPTION

The term “anode” represents an electrode material that is electrochemically oxidized during an electrodeposition process.

The term “angular alignment feature” represents a feature formed in a gap characterization fixture that serves as a reference for aligning an angular orientation of the gap characterization fixture.

The term “anode structure” represents a surface contacted by a fixture held in a substrate holder during a plating gap characterization process. An example anode structure is a high-resistance virtual anode.

The term “anolyte” represents a liquid environment in which an anode is located during electrodeposition.

The term “auto debubble (ADB) fixture” may generally represent an apparatus configured to be held within a substrate holder of an electrodeposition tool for removing bubbles contained in an electrodeposition cell.

The term “auto plating gap (APG) characterization fixture” may generally represent an apparatus configured to be held within a substrate holder of an electrodeposition tool for characterizing a plating gap of the electrodeposition tool.

The term “cathode” represents a conductive layer on a substrate that is grown during electrodeposition by the reduction of ions in a catholyte.

The term “catholyte” represents a liquid environment in which a cathode is located during electrodeposition.

The term “companion fixture” may generally represent an apparatus configured to be held within a substrate holder of an electrodeposition tool. A companion fixture can be used together with an APG characterization fixture for performing a gap characterization process on a pair of electrodeposition cells.

The term “contact surface” represents a surface on a gap characterization fixture configured to contact an anode structure of an electrodeposition tool during a plating gap characterization process.

The terms “electrodeposition”, “plating”, and variants thereof represent a process in which dissolved ions of an element are reduced on a substrate surface to form a film of the element.

The term “electrodeposition cell” may generally represent a station in an electrodeposition tool configured for processing a substrate via electrodeposition.

The term “electrodeposition tool” represents a machine configured to perform electrodeposition.

The term “electrodeposition cell” may generally represent a station in an electrodeposition tool configured for processing a substrate via electrodeposition.

The terms “fixture” and “gap characterization fixture” represent an apparatus configured to be held within a substrate holder of an electrodeposition tool for characterizing a plating gap of the electrodeposition tool.

The term “front-end module” may generally represent a module for receiving substrates external to a substrate processing tool, and for transferring substrates into a processing module of the tool.

The terms “gap” and “plating gap” represent a separation between a cathode and an anode structure in an electrodeposition tool during an eletrodeposition process.

The term “gap characterization measurement” and “gap measurement” represent a measurement of a spacing of a plating gap.

The term “hard touch” represents a contact between a gap characterization fixture and an anode structure that meets a measurement threshold.

The term “high-resistance virtual anode” (HRVA) represents a rigid structure positioned between a substrate holder and an anode of an electrodeposition tool through which ions flow from the anode to the cathode during electrodeposition.

The term “installation sensor” may generally represent a sensor configured to detect whether a maintenance fixture storage system is installed in a processing tool.

The term “level adjuster” and variants thereof represent any mechanism for adjusting a parallelism between a substrate holder and an anode structure in an electrodeposition tool.

The term “lift” refers to a mechanism for adjusting a spacing between a substrate holder and an anode structure in an electrodeposition tool.

The term “maintenance cycle” may generally represent a maintenance process performed on a substrate processing station. Example maintenance cycles include a gap characterization process and an auto debubbling cycle for an electrodeposition processing tool.

The term “maintenance fixture” may generally represent an apparatus that can be used to perform automated maintenance on a substrate processing tool. Example maintenance fixtures include an ADB fixture and an APG characterization fixture.

The term “maintenance fixture storage and handling system” may generally represent a storage apparatus for storing maintenance fixtures in a substrate processing tool, and one or more robots for transferring the maintenance fixtures between different locations within the processing tool. A maintenance fixture storage and handling system may use one or more robots that are also used for substrate handling.

The term “maintenance fixture storage system” may generally represent an apparatus configured to store one or more maintenance fixtures within a substrate processing tool.

The term “parallelism” and “cell parallelism” refer to an angular difference between a surface plane of a substrate in a substrate holder and a surface plane of an anode structure. The term “cell-to-cell parallelism” represents an angular difference between surface planes of the anode structures of two or more cells.

The term “plating cell” represents a station in an electrodeposition tool configured for processing a substrate.

The term “preselected plating gap spacing” represents a distance between a plane of a substrate holder interface of a gap characterization fixture and a contact surface of a protrusion of the gap characterization fixture.

The term “presence sensor” may generally represent a sensor configured to detect a presence of a maintenance fixture in a storage location of a maintenance fixture storage system.

The term “processing module” may generally represent a portion of a substrate processing tool that contains processing stations for performing processes on substrates.

The term “protrusion” represents a structure on a gap characterization fixture having a contact surface configured to contact an anode structure of an electrodeposition tool during a plating gap characterization process.

The term “robot system” may generally represent one or more robots configured to transfer maintenance fixtures and/or substrates between locations in a substrate processing tool.

The term “rotational torque” represents a torque produced by a motor driving rotation of a substrate holder.

The term “substrate” refers to a structure on which film may be deposited via electrodeposition. Example substrates include semiconductor wafers.

The term “substrate holder” represents a structure for holding a substrate during an electrodeposition process.

The term “substrate holder interface” represents a structure on a gap characterization fixture configured to contact a seal of a substrate holder of the electrodeposition tool.

The term “substrate processing station” may generally represent a station within a substrate processing tool that performs one or more processing techniques, such as electrodeposition, on a substrate.

The term “substrate processing tool” may generally represent a tool comprising at least one substrate processing station.

The term “threshold rotational condition” represents a threshold to which a measurable or observable condition related to rotation of a substrate holder is compared.

The term “user interface” may generally represent an interface with which a user can interact with components of a processing tool. A user interface may display information about the processing tool, allow the configuration of processing tool operation, and/or allow control of the tool during processing and maintenance.

As mentioned above, electrodeposition involves the electrochemical reduction of dissolved ions of a selected metal to an elemental state on a substrate surface, thereby forming a film of the selected metal on the substrate. In some examples, a substrate may comprise a semiconductor wafer.

Electrodeposition can be used, for example, to form conductive lines on a substrate by filling patterned trenches and vias in the substrate with metal. Excess metal can be removed by chemical mechanical polishing or other suitable process. Electrodeposition also may be used to form other conductive structures.

During electrodeposition, the substrate is supported in a substrate holder. An example substrate holder is described in more detail below. The substrate initially comprises a thin seed layer of metal as a cathode. The substrate with the seed layer of metal is positioned in a catholyte, and an electric current is applied to reduce metal ions in the catholyte onto the substrate surface and thereby increase a thickness of the cathode.

During the electrodeposition process, the substrate is positioned at a preselected distance from an anode structure. This distance may be referred to as a gap or a plating gap. Maintaining a suitably parallel gap between the substrate and the anode structure helps to achieve proper film deposition. If the substrate and anode structure are not sufficiently parallel, a deposited film may have poor uniformity across the substrate surface. Similarly, incorrect spacing between the substrate and anode structure also may impact deposition performance.

Thus, to ensure proper electrodeposition performance, a spacing of and/or parallelism of the gap can be characterized. The spacing and/or parallelism further can be adjusted if necessary. Some characterization methods use a laser fixture in place of the substrate in the substrate holder. The laser emits light toward the anode structure. The emitted laser light is used to take distance measurements at different angular locations around an anode structure as the substrate holder is rotated. These measurements then may be used to manually adjust a spacing of and/or an alignment of the substrate holder and/or anode structure.

However, a laser-based characterization process may be intrusive, labor-intensive, and/or costly. For, example, the process may involve taking an electroplating cell offline and draining the cell. Further, if misalignment is found between the substrate holder and the anode structure, multiple manual adjustments may be necessary to ensure that the anode structure is suitably parallel to the substrate surface.

Accordingly, examples are disclosed herein that relate to automated gap characterization processes for an electrodeposition tool. Examples are also disclosed that relate to fixtures used in gap characterization processes. Briefly, the disclosed example fixtures have a shape configured to fit within a substrate holder. The fixtures comprise a substrate holder interface configured to interface with a seal in a substrate holder. When secured in the substrate holder, a protrusion on the fixture is configured to contact an anode structure of a plating cell. A dimension of the fixture between a plane of the substrate interface and a distal end of the protrusion corresponds to a preselected plating gap spacing. In an example characterization process, the protrusion is contacted to the anode structure. Then, a rotational torque is applied to the substrate holder. The substrate holder is lifted from the anode structure while the rotational torque is applied. In another example process, the substrate holder is moved toward the anode structure while a rotational torque is applied to sense contact. In either example, a lift position at which the substrate holder meets a threshold rotational condition corresponds to a gap characterization measurement. For example, where the substrate holder is moved from the anode structure to perform a measurement, a threshold rotational condition may correspond to a threshold degree of rotation. In contrast, where the substrate holder is moved toward the anode structure to perform a measurement, a threshold rotational condition may correspond to a cessation of rotation. In some examples, measurements may be taken at different angular locations to characterize a parallelism of the substrate holder and anode structure. The disclosed examples may be performed using substrate handling systems within a tool and without draining a plating cell. Thus, the disclosed examples may offer advantages over laser-based gap characterization processes.

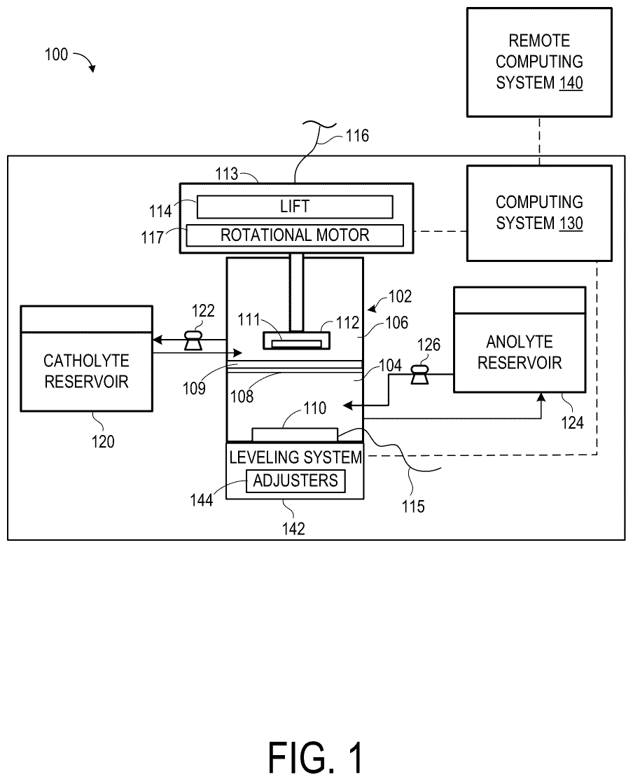

Prior to discussing these examples in more detail, FIG. 1 schematically shows a block diagram of an example electrodeposition tool 100. Electrodeposition tool 100 comprises a plating cell 102 including an anode chamber 104 and a cathode chamber 106. Electrodeposition tool 100 further comprises a selective transport barrier 108 and high resistance virtual anode 109 (HRVA). Anode chamber 104 comprises an anode 110. Anode chamber 104 further comprises an anolyte in contact with anode 110. Cathode chamber 106 comprises a catholyte. The catholyte comprises an ionic species to be deposited on a substrate 111 as a metal by electrochemical reduction. Anode 110 comprises the metal being deposited. Electrochemical oxidation of anode 110 replenishes the ionic species consumed by the electrodeposition process. In some examples, catholyte is directed as a flow between HRVA 109 and substrate 111 during an electrodeposition process.

Selective transport barrier 108 allows a separate chemical and/or physical environment to be maintained within anode chamber 104 and cathode chamber 106. For example, selective transport barrier 108 may be configured to prevent non-ionic organic species from crossing the barrier while allowing metal ions to cross the barrier. HRVA 109 comprises an ionically resistive element that approximates a suitably constant and uniform current source in proximity to a substrate cathode.

Substrate holder 112 is coupled to a substrate holder movement system 113 including a lift 114 that is configured to adjust a spacing between substrate holder 112 and HRVA 109. For example, lift 114 may lower substrate holder 112 to position substrate 111 within the catholyte for electrodeposition. Lift 114 further may raise substrate holder 112 from the catholyte after electrodeposition. Substrate holder movement system 113 further may include components to control the opening and closing of substrate holder 112.

The catholyte may be circulated between cathode chamber 106 and a catholyte reservoir 120 via a combination of gravity and one or more pumps 122. Likewise, the anolyte may be stored in and replenished from an anolyte reservoir 124. Anolyte may be circulated through anolyte reservoir 124 and anode chamber 104 via a combination of gravity and one or more pumps 126.

In some electrodeposition tools, plating operations maybe performed in parallel on multiple substrates using multiple plating cells. In some such examples, central catholyte and/or anolyte reservoirs may supply multiple plating cells with catholyte and/or anolyte. In other such examples, separate catholyte and/or anolyte reservoirs may be used to supply multiple plating cells. In yet other examples, an electrodeposition tool may comprise a single plating cell. Where an electrodeposition tool comprises multiple plating cells, a single lift may be configured to lift two or more substrate holders for two or more different plating cells.

Substrate holder 112 is lowered by lift 114 toward HRVA 109 after substrate 111 is loaded into substrate holder 112. Substrate 111 faces a surface of the HRVA 109, and is spaced from HRVA 109 by a plating gap during electrodeposition, as mentioned above. An electric field is established between anode 110 and substrate 111. This field drives dissolved metal cations from anode chamber 104 into cathode chamber 106. At the substrate 111, the metal cations are electrochemically reduced to deposit on the cathode layer on substrate 111. An anodic potential is applied to anode 110 via an anode electrical connection 115 and a cathodic potential is provided to the cathode of substrate 111 via a cathode electrical connection 116 to form a circuit. In some examples, substrate holder 112 may be rotated via a rotational motor 117 during electrodeposition.

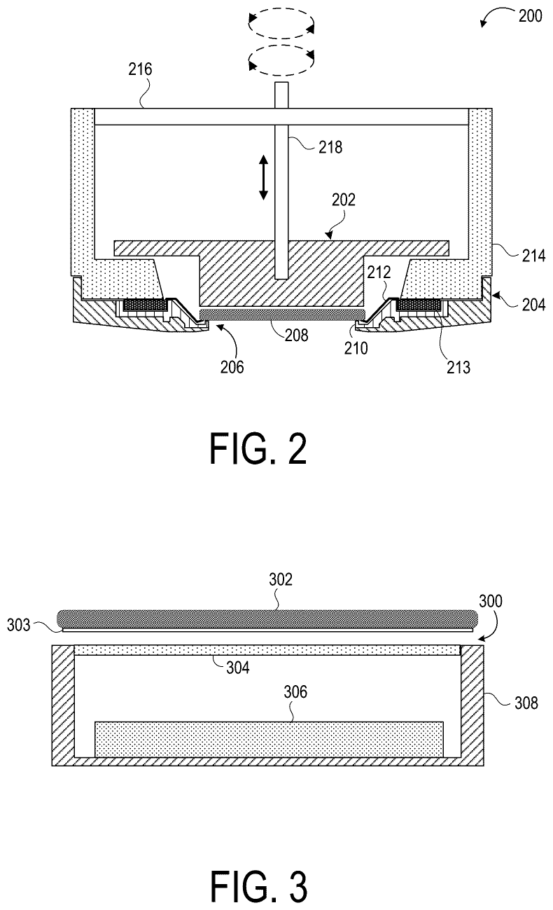

FIG. 2 shows a schematic sectional view of an example substrate holder 200 configured to hold a substrate 208 during electrodeposition. Substrate holder 200 is an example of substrate holder 112 of FIG. 1. Substrate holder 200 takes the form of a clamshell assembly comprising a cone 202 and a cup 204. Cup 204 comprises a substrate interface 206 that is configured to support a substrate 208 comprising an electrically conductive cathode layer. Substrate 208 is an example of substrate 111 of FIG. 1. Substrate interface 206 comprises a seal 210 and one or more electrical contacts 212 (hereinafter “electrical contacts 112”). Seal 210 makes physical contact with substrate 208 to prevent catholyte from reaching electrical contacts 212 during electrodeposition. Electrical contacts 212 are attached to a metal frame 213, which provides mechanical support and electrical conduction.

Cup 204 is supported by struts 214, which connect to other portions of substrate holder 200, such as a lift. A position of cone 202 relative to cup 204 is controllable to selectively press substrate 208 against seal 210 with cone 202, and to allow substrate 208 to be removed from cup 204. Substrate holder 200 further comprises a top plate 216 and a spindle 218. Spindle 218 may be mechanically connected to a motor (for example, rotational motor 117 of FIG. 1) controllable to rotate substrate holder 200.

Substrate holder 200 is lowered towards a HRVA or other suitable anode structure by a lift (for example, lift 114 of FIG. 1) such that the exposed surface of substrate 208 is immersed in catholyte during electrodeposition. Downward force from cone 202 helps form a fluid tight seal between substrate 208 and seal 210 during electroplating. This helps to isolate electrical contacts 212 from the catholyte.

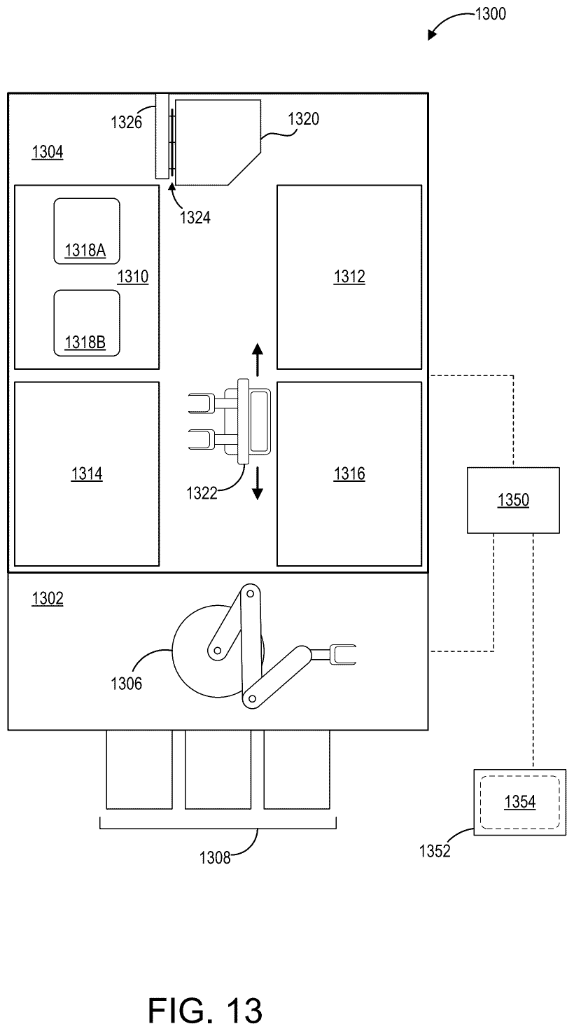

Returning to FIG. 1, electrodeposition tool 100 further comprises a computing system 130, aspects of which are described in more detail below with regard to FIG. 13. Computing system 130 may include instructions executable to control any suitable functions of electrodeposition tool 100, such as electrodeposition processes, wafer loading/unloading processes, and gap characterization processes.

A gap characterization process may be used to characterize a parallelism of the substrate holder 112 compared to the HRVA 109. The resulting measurement(s) may be used to adjust a leveling system 142 of electrodeposition tool 100, for example, when a measured parallelism is outside of a threshold. Leveling system 142 further may be used to adjust a spacing of a gap between substrate 111 and HRVA 109 if a characterized gap is outside of a threshold. Leveling system 142 may include a plurality of leveling adjusters 144 (e.g. height-adjustable support legs) coupled to the plating cell 102 to allow a plane of HRVA 109 to be adjusted. In some examples, each leveling adjuster 144 includes a motor to allow for computing system 130 to automatically control a height of each leg. In other examples, each leveling adjuster may be manually adjustable. For example, each leveling adjuster may comprise a screw that can be turned to raise or lower a corresponding location on the plating cell 102.

In some examples, computing system 130 may be configured to communicate with a remote computing system 140 via a suitable computer network. Remote computing system 140 may comprise any suitable computing system, such as a networked workstation computer, an enterprise computing system, and/or a cloud computing system, as examples. It will be understood that remote computing system 140 may be in communication with and control a plurality of electrodeposition tools in some examples.

FIG. 3 schematically shows an example plating gap 300 between a substrate 302 comprising a cathode layer 303 and an anode structure 304 during an electrodeposition process. Anode structure 304 may represent a HRVA in this example, and is positioned between an anode 306 positioned within an anode chamber 308 and substrate 302.

As mentioned above, maintaining a consistent gap and suitably close parallelism between substrates and anode structure 304 may help to ensuring the deposition of a suitably uniform metal layer on substrate 302. However, as mentioned above, current laser-based methods of characterizing a plating gap may be disruptive to tool operation. Thus, a mechanical gap characterization process utilizing a gap characterization fixture configured to contact an anode structure in a gap characterization measurement may allow for more convenient characterization.

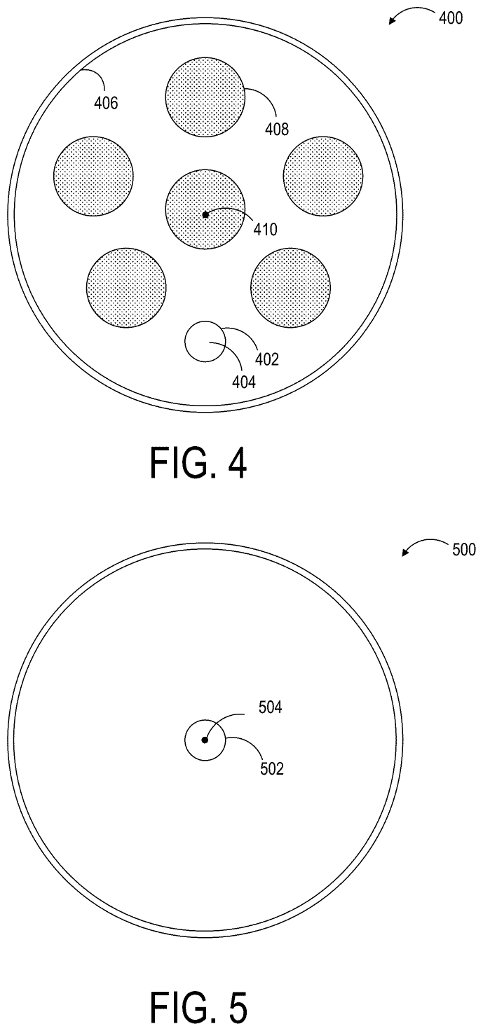

FIG. 4 schematically shows an example gap characterization fixture 400 for characterizing a spacing of a plating gap between a substrate surface and an anode structure. Gap characterization fixture 400 has a circumferential shape configured to fit within a substrate holder of a plating cell to be characterized. In this example, gap characterization fixture 400 comprises a generally circular shape that matches the shape of a semiconductor wafer.

Gap characterization fixture 400 further comprises a protrusion 402. Protrusion 402 is positioned to extend toward and contact an anode structure during a gap characterization process. As such, protrusion 402 comprises a contact surface 404 configured to contact the anode structure. In some examples, contact surface 404 comprises a smooth radius of curvature. This may help to ensure that the protrusion has no edges that may catch on any uneven surface on an anode structure when gap characterization fixture 400 is rotated during a characterization process, as described below.

Gap characterization fixture 400 further comprises a substrate holder interface 406. Substrate holder interface 406 is configured to contact a seal of a substrate holder. Substrate holder interface 406 may have a similar thickness as an intended substrate (e.g. a semiconductor wafer) in some examples. Further, in some examples, substrate holder interface 406 may comprise a thinner profile than an adjacent region of gap characterization fixture 400. The thicker region adjacent to the substrate holder interface 406 may provide rigidity to gap characterization fixture 400 to help prevent deformation during a gap characterization process. Gap characterization fixture 400 is configured such that a distance between a plane of substrate holder interface 406 and contact surface 404 of the protrusion 402 corresponds to a preselected plating gap spacing.

As mentioned above, it may be desirable for a gap characterization fixture to be sufficiently rigid to avoid deformation during a gap characterization process. Likewise, it may be desirable for the gap characterization fixture to be relatively lightweight so that it may be handled by a substrate handling system to facilitate loading and unloading. Thus, in some examples, the gap characterization fixture 400 may be formed from a rigid material. Examples include various polymers, such as polyetheretherketone (PEEK), polyetherketoneketone (PEKK), and/or other polyaryletherketone (PAEK) polymers. Other example materials may include various polycarbonates, polystyrenes, epoxy plastics, acrylic plastics, phenolic plastics, and polyphenylene sulfide (PPS). Yet other example materials include suitably rigid and strong metals, such as titanium or stainless steel.

To reduce a weight of the fixture, gap characterization fixture 400 may comprise one or more recesses. The depicted gap characterization fixture 400 comprises a plurality of recesses 408. In various examples, recesses 408 may extend partially through gap characterization fixture 400 or fully through gap characterization fixture 400. Recesses 408 may be arranged to align a center of mass of gap characterization fixture 400 with a rotational center of gap characterization fixture 400. This may allow gap characterization fixture 400 to be spun dry without causing wobble. The depicted example comprises a plurality of circular-shaped recesses 408. In other examples, any other suitable number, shapes, and sizes of recesses may be formed in a surface of a gap characterization fixture.

Protrusion 402 is offset from a rotational center 410 of gap characterization fixture 400. Offsetting the protrusion from the rotational center of gap characterization fixture 400 may allow both a gap spacing and a parallelism of a substrate holder and anode structure to be characterized. For example, a plurality of gap characterization measurements may be made at different angular positions, as described in more detail below. A difference between a highest measurement and a lowest measurement may correspond to a parallelism measurement. Further, an average measurement may correspond to a gap spacing in some examples. In other examples, a protrusion may be centered for characterizing a gap spacing, but not parallelism. FIG. 5 shows an example gap characterization fixture 500 having a protrusion 502 located at a rotational center 504 of fixture 500 for gap spacing characterization but not parallelism characterization.

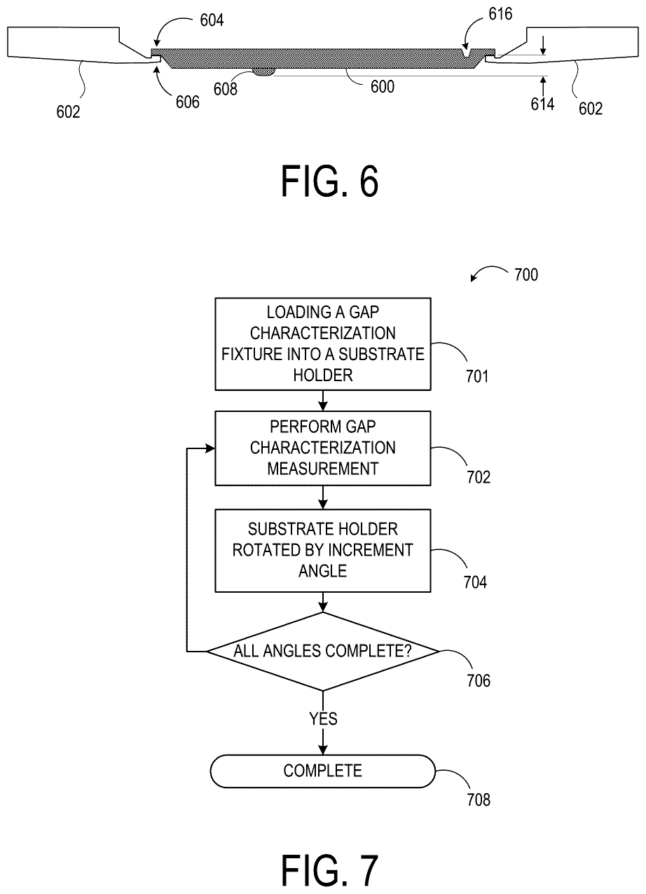

FIG. 6 schematically shows an example gap characterization fixture 600 positioned in a cup portion of a substrate holder 602. Substrate holder 602 is shown here in a simplified manner. Gap characterization fixture 600 includes a substrate holder interface 604 configured to contact a seal 606 of substrate holder 602. As mentioned above, substrate holder interface 604 may comprise a thinner profile than an adjacent region of gap characterization fixture 600. For example, the substrate holder interface may have a similar thickness as an intended substrate, while an adjacent region may have a greater thickness for rigidity.

Gap characterization fixture 600 further comprises a protrusion 608. Protrusion 402 may have a curvature with any suitable radius. Examples include radii within a range of 0.5 to 1.5 inches. Gap characterization fixture 600 is configured such that a distance 614 between a plane of substrate holder interface 604 and a contact surface of protrusion 608 corresponds to a preselected plating gap spacing. The preselected plating gap spacing corresponds to a desired gap to be maintained between a substrate and an anode structure during an electrodeposition process.

In some examples, gap characterization fixture 600 further includes one or more angular alignment feature(s) 616. Angular alignment feature 616 serves as a reference so that an angular orientation of gap characterization fixture 600 can be determined by sensing. Angular alignment feature 616 further may interface with a corresponding feature in a fixture storage and handling system (examples of which are described in more detail below) to allow gap characterization fixture 600 to be stored in a known angular position. For example, angular alignment feature 616 may interface with a mechanical pin in a fixture storage and handling system, or be sensed by an optical detector. The use of angular alignment feature 616 may facilitate loading of gap characterization fixture 600 into a substrate holder in a known angular orientation.

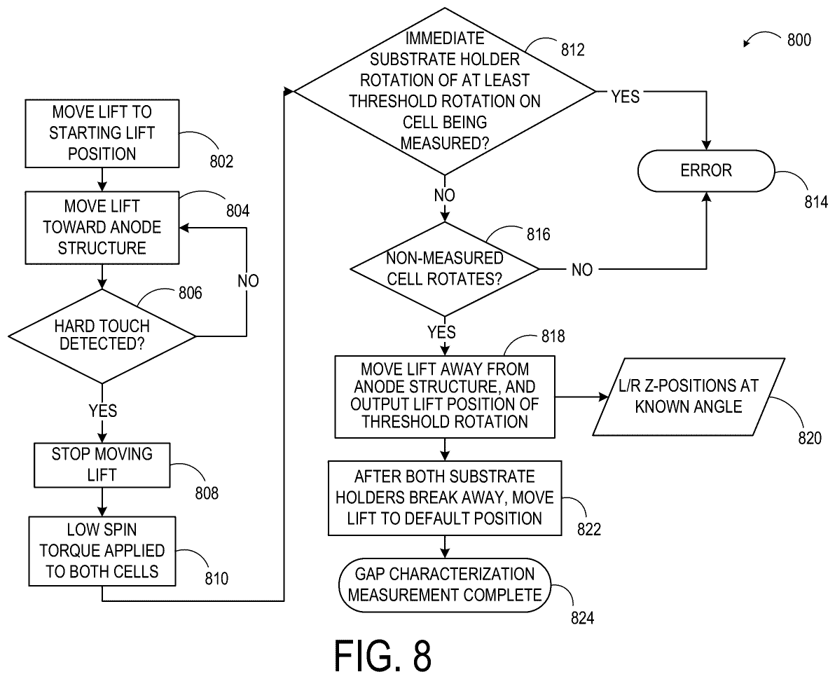

A gap characterization fixture as described herein may be used in a gap characterization process for an electrodeposition tool. FIG. 7 shows a flow diagram of an example method 700 for characterizing a plating gap of an electrodeposition tool. Method 700 includes, at 701, loading a gap characterization fixture into a substrate holder. Next, method 700 includes, at 702, performing a gap characterization measurement, as described in more detail with reference to FIG. 8. Continuing, method 700 includes, at 704, rotating the substrate holder by an increment angle. If not all angles are complete, at 706, a gap characterization measurement is performed at a next increment angle. Once measurements have been made at all angles, the process completes at 708.

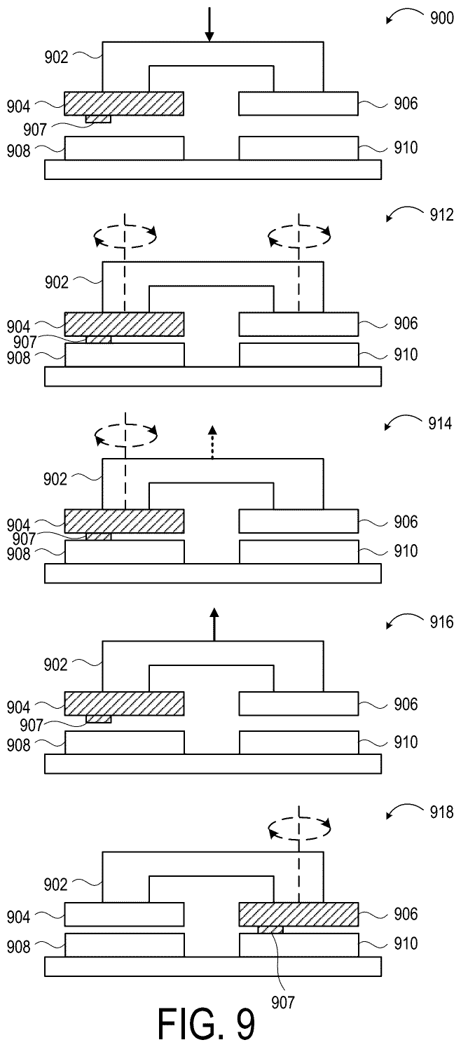

FIG. 8 shows a flow diagram of an example method 800 for performing a gap characterization measurement. Method 800 is an example implementation of 702 of FIG. 7. Method 800 is described in the context of characterizing a gap on a tool comprising two plating cells using a common lift for the substrate holder of each plating cell. An example of such a tool is depicted schematically in FIG. 9. However, method 800 may be utilized for any other suitable plating tool configuration. It will be understood that some processes of method 800 may be omitted or modified, and/or that additional processes may be performed in various implementations. While the substrate holders are arranged vertically above the plating cell in this example, in other examples a substrate holder and plating cell may have any other suitable orientation relative to one another, including horizontal and diagonal relationships relative to a direction of gravity.

Method 800 includes, at 802, moving the lift to a starting position, wherein “position” refers to a position of the lift relative to the plating cell. At 804, the lift moves the substrate holder toward the anode structure, until a hard touch is detected at 806. FIG. 9 schematically represents the coupling of two substrate holders to a common lift by support 902. An example gap characterization fixture within a substrate holder of a first plating cell is schematically illustrated at 904. A “blank” fixture within a substate holder of a second plating cell is shown at 906. Downward motion of gap characterization fixture 904 toward an anode structure 908 is shown at 900.

A hard touch of a protrusion 907 of gap characterization fixture 904 to an anode structure 908 of a first plating cell may be detected in any suitable manner. As one example, a hard touch may be detected by monitoring a torque of a lift motor, and detecting when a torque threshold is reached. As another example, a velocity of the movement of the substrate holder and/or lift may be monitored, and the hard touch may be detected once the velocity decreases to below a threshold velocity. As yet another example, the substrate holders may be lowered toward the anode structures while rotating. When the gap characterization fixture contacts the anode structure, the rotation is slowed or stopped by the contact, which can be measured as a change in rotational torque. A threshold change in rotational torque can correspond to a hard touch. It will be understood that any suitable technique or combination of techniques may be used to detect a hard touch between the gap characterization fixture and the anode structure.

In some examples, a low pass filter may be applied to hard touch measurements to filter transient measurement fluctuations. Further, where torque measurements are used to detect a hard touch, a baseline torque may be determined before the gap characterization process starts. A measured torque then can be corrected for the baseline torque.

Upon detecting a hard touch at 806, method 800 comprises stopping motion of the lift, at 808. Then, a suitably low rotational torque (“spin torque”) is applied to the substrate holder of both plating cells, at 810, to perform one or more error checks. FIG. 9 shows, at 912, a rotational torque being applied to the first substrate holder and the second substrate holder.

As one example error check, if there is an immediate substrate holder rotation of at least a threshold magnitude on the cell being measured (the substrate holder holding the gap characterization fixture), at 812, then an error notification is output, at 814. This may indicate that no hard contact is made between the gap characterization fixture and anode structure.

As another example error check, if the substrate holder of the non-measured cell does not rotate when the rotational torque is applied, then an error notification is output at 814. Because the second substrate holder holds a blank fixture 906, the second substrate holder should be able to rotate when a suitably low rotational torque is applied.

Where no errors are detected, method 800 next comprises, at 818, moving the lift away from the anode structure at a relatively slow velocity. While moving the lift away, the substrate holder with the gap characterization fixture is monitored to detect rotation that exceeds a threshold rotational condition, such as a rotational movement of a threshold magnitude. The lift position where each substrate holder begins to rotate is then output as a gap characterization measurement. FIG. 9 schematically shows, at 914, the lift moving upward while a rotation is applied to the first substrate holder holding gap characterization fixture 904. After both substrate holders break away, the lift is moved back to a default position, at 822, and the gap characterization measurement for an angular position of the first plating cell is complete, at 824. FIG. 9 shows the lift being moved upward, at 916. These steps may be repeated for multiple angular positions of the first substrate holder in some examples.

In this two-cell example, the gap characterization fixture may be switched to the second plating cell, and the blank switched to the first plating cell. The gap characterization measurement process then may be repeated for the second cell. For example, protrusion 907 is shown contacting an anode structure 910 of a second cell at 918.

As mentioned above, in other examples, a gap may be characterized based upon the substrate holder being rotated while being moved toward the anode structure, rather than when lifted from the anode structure. In such an example, a gap characterization measurement may correspond to a position at which a threshold rotational condition that indicates contact with the anode structure is met. Any suitable threshold rotational condition may be applied. Examples include a threshold increase in rotational torque, a threshold level of rotational torque, and/or a cessation of rotation.

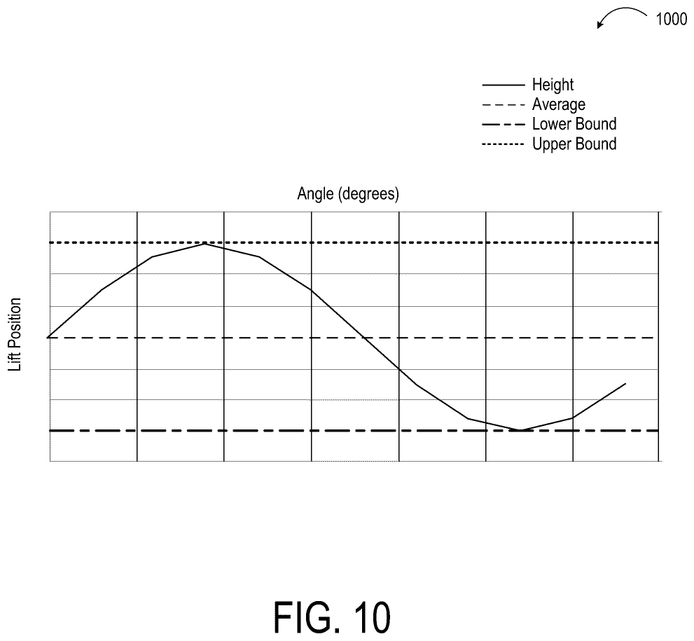

As mentioned above, gap characterization measurements may be performed for a plurality of angular positions with respect to the anode structure of a plating cell. FIG. 10 shows an example graph 1000 of lift position versus angular position determined by gap characterization. The sinusoidal shape of the graph 1000 indicates that the anode structure is angled relative to the gap characterization fixture. This data can be used to adjust a position of an anode structure, such as a HRVA, with respect to the substrate holder.

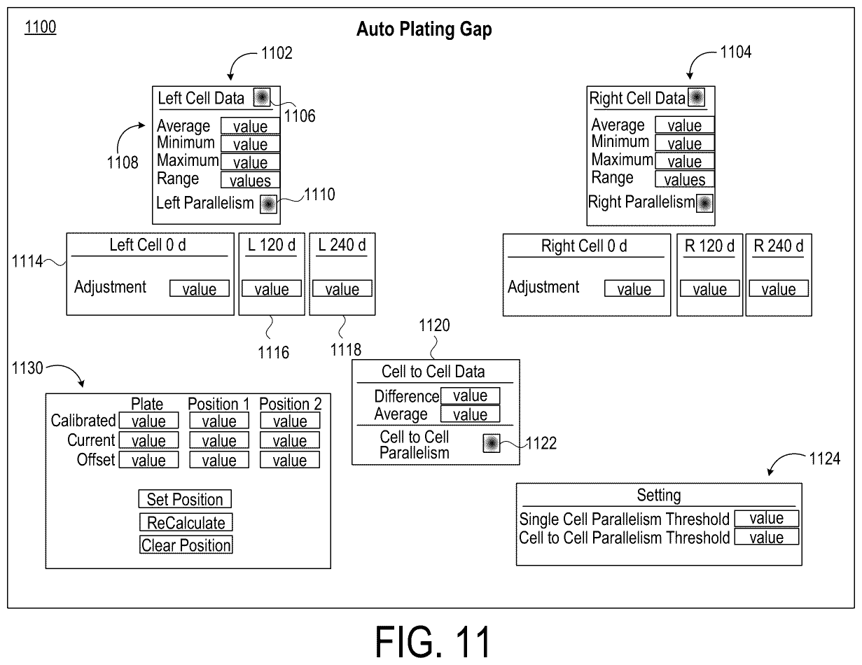

FIG. 11 shows an example user interface 1100 displayed on a display device of an electrodeposition system comprising two plating cells with a common lift. Data fields for the left cell are shown at 1102. Data fields for the right cell are shown at 1104. Cell data includes an indicator, shown for the left cell at 1106, that indicates whether data was returned successfully from the lift controller. Data is returned successfully if no errors were encountered during execution of the gap characterization measurement, such as the errors described with regard to FIGS. 8 and 9.

Cell data further includes, for the left cell at 1108, average, minimum, maximum, and range of the gap characterization measurements, e.g. taken for a plurality of different rotational angles of the substrate holder. Cell data also includes, for the left cell at 1110, a cell parallelism indicator that indicates whether a cell parallelism measurement is below or above a cell parallelism threshold. As mentioned above a difference between a lowest measurement and highest measurement may correspond to a parallelism measurement. A lower magnitude indicates that the HRVA is closer to being parallel with the plane of the gap characterization fixture. A cell parallelism measurement of zero indicates that these planes are parallel. If the cell parallelism measurement is outside of a permissible range, then the indicator 1110 displays an appropriate status.

As mentioned above, the plurality of gap characterization measurements may be used to adjust a leveling system. In some examples, the user interface 1100 may display information regarding adjustments to make to the leveling system. Here, adjustment data is shown at 1114, 1116, and 1118 for level adjusters located at 0 degrees, 120 degrees, and 240 degrees of the left cell respectively. In other examples, level adjusters may have any other suitable angular locations. Each display box 1114, 1116, and 1118 shows an adjustment to be applied to help adjust parallelism. In some examples, a leveling system may comprise motors for automatically adjusting the height of each leveling adjuster of the leveling system, while in other examples an adjustment may be made manually. In such examples, the leveling system adjustment may be performed automatically after measurement by controlling motors in a leveling system.

User interface 1100 further displays cell-to-cell data at 1120. Cell-to-cell data 1120 includes a difference between the left and right cell average lift heights, and an average lift height for the measurements for both cells. An indicator at 1122 displays whether a determined cell-to-cell parallelism measurement is outside of a permissible range.

At 1124, user-definable settings are shown for single cell parallelism threshold and cell-to-cell parallelism. Further, at 1130, lift position offsets may also be set by user input. New lift positions can be calculated based on user input position offsets. The lift positions can be recalculated if the position offsets are changed after gap characterization measurement data has already been collected. Individual position offsets may be selected for updating in the lift controller, and selected positions can be set and saved to the lift controller.

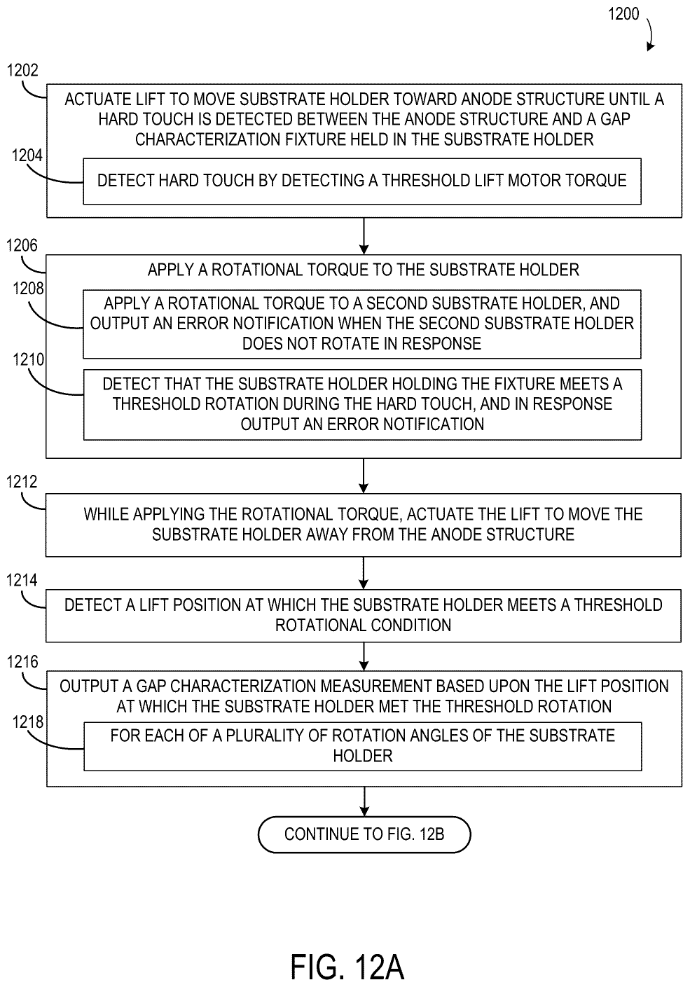

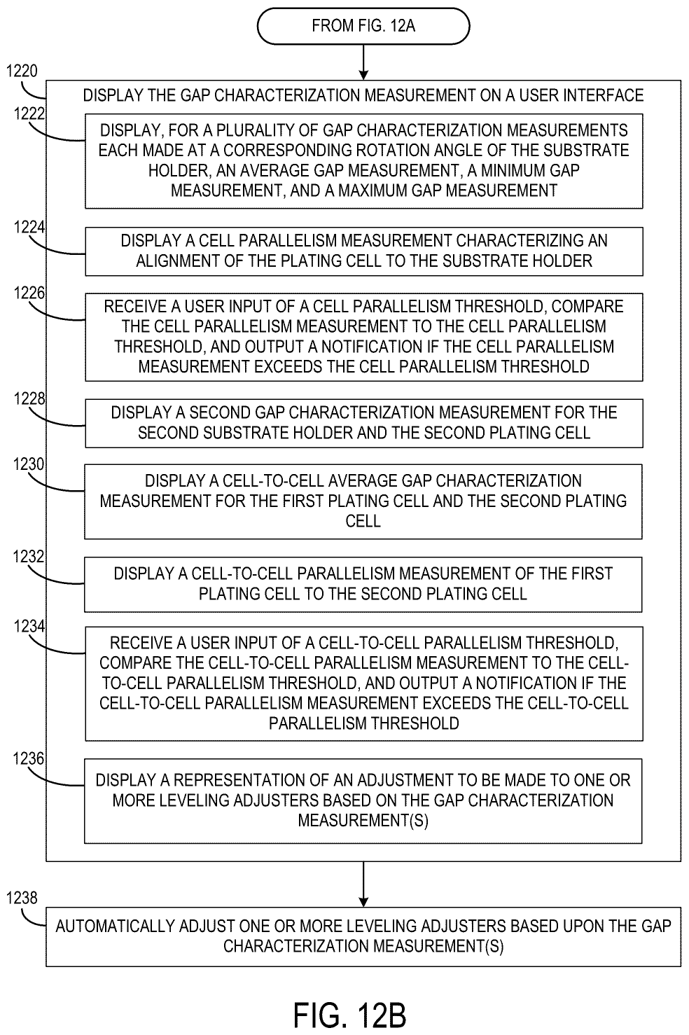

FIGS. 12A-B show a flow diagram of an example 1200 for operating an electrodeposition system to perform gap characterization. Method 1200 may be controlled by a computing system of an electrodeposition tool. The example of method 1200 is in the context of a process in which a substrate holder is moved toward an anode structure until a hard touch is detected, and then lifted while a rotational torque is applied. However, as described above, in other examples, a rotational torque may be applied while a substrate holder is moved toward an anode structure to obtain a gap characterization measurement.

Method 1200 includes, at 1202, actuating a lift to move a substrate holder toward an anode structure of an electrodeposition tool, until a hard touch is detected between the anode structure and a gap characterization fixture held in the substrate holder. In some examples, a lift may be configured to move two or more substrate holders for two or more different plating cells.

In some examples, a hard touch may be detected by detecting a threshold torque of a lift motor, at 1204, e.g. as an absolute value or a change in torque. In other examples, a hard touch may be detected by a threshold or threshold change in velocity. In yet other examples, a hard touch may be detected by a threshold or threshold change in rotational torque of the substrate holder in which the fixture is located.

Method 1200 further includes, after detecting the hard touch, at 1206, stopping the lift and applying a rotational torque to the substrate holder. In examples where a lift is coupled to two plating cells, a rotational torque may also be applied to a second substrate holder, where the second substrate holder holds a blank fixture or standard wafer, as described by example in regard to FIG. 9. Method 1200 includes outputting an error notification when the second substrate holder does not rotate in response, at 1208. This is an example of an error check that may be performed in a two-cell system. As another error check, method 1200 also includes, at 1210, detecting that the substrate holder that holds the fixture meets a threshold rotation during the hard touch, and in response output an error notification.

If no errors are detected, method 1200 comprises, while applying the rotational torque, actuating the lift to move the substrate holder away from the anode structure, at 1212. This movement may be done at a relatively slow rate to help detect when the substrate holder begins to rotate in response to the rotational torque. Next, method 1200 includes, at 1214, detecting a lift position at which the substrate holder meets a threshold rotational condition. At 1216, method 1200 includes outputting a gap characterization based upon the lift position at which the substrate holder met the threshold rotational condition. The same processes may be repeated for each of a plurality of rotation angles of the substrate holder, at 1218.

Continuing with FIG. 12B, method 1200, includes, at 1220, displaying the gap characterization measurement on a user interface. The user interface may also display, at 1222, for a plurality of gap characterization measurements each made at a corresponding rotation angle of the substrate holder an average gap measurement, a minimum gap measurement, and a maximum gap measurement. The user interface may further display, at 1224, a cell parallelism measurement characterizing an alignment of the plating cell to the substrate holder. The cell parallelism measurement may be determined from the plurality of gap characterization measurements each made at a corresponding rotation angle of the substrate holder. In some examples, the user interface may allow user input of various settings and thresholds. Thus, method 1200 includes, at 1226, receiving a user input of a cell parallelism threshold, comparing the cell parallelism measurement to the cell parallelism threshold, and outputting a notification if the cell parallelism measurement exceeds the cell parallelism threshold. Exceeding the cell parallelism threshold may indicate that the plating cell is not aligned in a sufficiently parallel manner with the substrate holder.

Method 1200 further includes, at 1228, displaying a second gap characterization measurement for the second substrate holder and the second plating cell, after performing the same gap characterization steps for the second plating cell. At 1230, method 1200 includes displaying a cell-to-cell average gap characterization measurement for the first plating cell and the second plating cell. At 1234, method 1200 also includes displaying a cell-to-cell parallelism measurement of the first plating cell to the second plating cell. Method 1200 further includes, at 1234, receiving a user input of a cell-to-cell parallelism threshold, comparing the cell-to-cell parallelism measurement to the cell-to-cell parallelism threshold, and outputting a notification if the cell-to-cell parallelism measurement exceeds the cell-to-cell parallelism threshold. Exceeding the cell-to-cell parallelism threshold may indicate that the plating cells are not aligned in a sufficiently parallel manner with each other.

As mentioned above, the data determined from the gap characterization measurements may be used to adjust a level of the plating cell in order to align the HRVA to the substrate holder. Such adjustments can be done by controlling motors that adjust leveling adjusters coupled to the base of the plating cell. The leveling adjusters can be lowered or raised in height, allowing fine adjustments to be made. In other examples, information relating to the determined adjustments may also be displayed on the user interface to inform a user of the adjustments to be made. Thus, method 1200 includes, at 1236, displaying a representation of an adjustment to be made to one or more leveling adjusters based on the gap characterization measurement(s). Method 1200 further includes, at 1238, automatically adjusting one or more leveling adjusters based upon the gap characterization measurement(s).

Some substrate processing tools may comprise multiple processing stations. When performing manual maintenance on one substrate processing station of a tool, other processing stations and/or wafer handling robots within the processing tool may be idled. Additionally, performing a maintenance cycle manually may expose maintenance personnel to chemistries, such as catholyte and/or anolyte solutions.

Accordingly, examples are disclosed herein that relate to a maintenance fixture storage and handling system that can facilitate performing automated maintenance cycles on substrate processing stations of a substrate processing tool. The disclosed examples comprise a maintenance fixture storage system located within a processing tool for storing maintenance fixtures. The maintenance fixture storage and handling system further comprises a handling system comprising one or more robots for handling movement of maintenance fixtures between locations within a processing tool. For example, the handling system may transfer a maintenance fixture from a storage location of the maintenance fixture storage system to a substrate processing station, and back to the storage system. The handling system also may transfer maintenance fixtures between substrate processing stations. By utilizing a maintenance fixture storage and handling system internal to a processing tool, the disclosed examples may facilitate performing maintenance cycles with less downtime. The disclosed examples also may help to avoid exposure of processing chemistries to maintenance personnel.

FIG. 13 schematically shows an example substrate processing tool 1300 comprising an example maintenance fixture storage and handling system. Substrate processing tool 1300 comprises a front-end module 1302 for receiving substrates from external to substrate processing tool 1300, and a substrate processing module 1304 for processing substrates. Front-end module 1302 comprises a front-end robot 1306 configured to transfer substrates from a substrate transfer station 1308 into substrate processing module 1304. Front-end robot 1306 is further configured to transfer processed substrates from substrate processing module 1304 to substrate transfer station 1308 for offloading and/or further processing.

Substrate processing module 1304 comprises one or more substrate processing stations 1310, 1312, 1314, 1316. Substrate processing stations 1310 and 1312 each comprise an electrodeposition station for performing electrodeposition on a substrate. Substrate processing station 1314 comprises a pre-processing station for performing pre-processing substrate treatments such as pre-rinsing. Substrate processing station 1316 comprises a post-processing station for performing post-processing substrate treatments such as rinsing, cleaning, or edge bevel removal. The post-processing station may also be used for rinsing maintenance fixtures. While the example shown comprises four substrate processing stations, in other examples, a substrate processing module may comprise any other suitable number processing stations in any suitable arrangement. Furthermore, a substrate processing station may comprise two or more cells for processing substrates in parallel. For example, as depicted in FIG. 13, substrate processing station 1310 comprises two electrodeposition cells 1318A, 1318B. Other processing stations in substrate processing tool 1300 also may each be configured to process two or more substrates in parallel.

Substrate processing module 1304 further comprises a maintenance fixture storage and handling system comprising a maintenance fixture storage system 1320 and a robot system 1322. Maintenance fixture storage system 1320 is configured to hold various maintenance fixtures for use in automated maintenance cycles performed on substrate processing stations. One example comprises an auto debubble (ADB) fixture which can be used by an electrodeposition station to perform an auto debubbling maintenance cycle. Debubbling is a process in which bubbles suspended within or trapped underneath a HRVA are removed to help ensure consistent electrodeposition performance. Another example comprises an auto plating gap (APG) characterization fixture that can be used by an electrodeposition station to perform a gap characterization process.

Maintenance fixture storage system 1320 comprises a mounting system 1324 for mounting onto an interior surface (e.g. a wall 1326) of the substrate processing module. In other examples, maintenance fixture storage system 1320 may be mounted in any other suitable location (e.g., floor, ceiling) within substrate processing module 1304. In some examples, the maintenance fixture storage system 1320 may be removably mounted within substrate processing module 1304 for relatively fast removal and reinstallation. Mounting system 1324 may comprise any suitable mechanism for mounting to wall 1326. In some examples, mounting system 1324 comprises a kinematic mounting system, as described in more detail below.

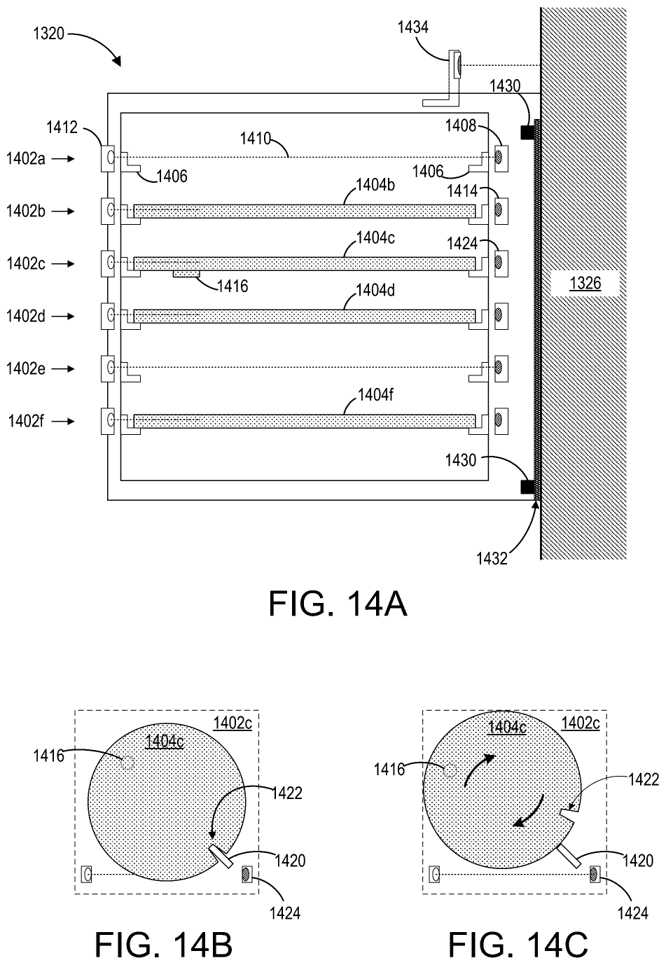

FIG. 14A shows a side-view of example maintenance fixture storage system 1320. Maintenance fixture storage system 1320 comprises one or more maintenance fixture storage locations (here shown as storage locations 1402a-f) for storing one or more maintenance fixtures (here shown as 1404b, 1404c, 1404d, 1404f). As shown at 1402a, each maintenance fixture storage location comprises one or more fixture supports 1406 and a presence sensor 1408. Each presence sensor 1408 is configured to output a signal indicative of a presence or absence of a maintenance fixture in the maintenance fixture storage location. As described in more detail below, the sensor outputs can be used to control a user interface to display whether a maintenance fixture is currently located in each storage location.

In the example depicted in FIG. 14A, each presence sensor comprises an optical sensor configured to detect a light beam output by a light source. The light source and optical sensor of each presence sensor are positioned such that the pathway of the light beam is blocked by a maintenance fixture placed in the corresponding storage location. Here, as light beam 1410 from light source 1412 is unimpeded, presence sensor 1408 detects light beam 1410 and outputs a signal indicative of an absence of a maintenance fixture in maintenance fixture storage location 1402a. On the other hand, presence sensor 1414 does not detect a light beam, and therefore outputs a signal indicative of a presence of maintenance fixture 1404b at maintenance fixture storage location 1402b. In other examples, the light source and/or optical sensors may be placed in any other suitable locations. Further, in some examples, the presence sensor may be configured to detect a light beam reflected from the maintenance fixture.

In other examples, a presence sensor may comprise a mechanical switch that is activated when a maintenance fixture is stored in the storage location. In further examples, a presence sensor may comprise a radiofrequency identification (RFID) sensor, near-field communication (NFC) sensor, a capacitive sensor, an inductive sensor, and/or any other suitable sensor.

Maintenance fixture storage system 1320 may be configured to store any suitable maintenance fixtures. In this example, maintenance fixture 1404b comprises an ADB fixture for use in auto debubbling maintenance cycles. Further, maintenance fixture 1404c comprises an APG characterization fixture for use in a gap characterization process. Maintenance fixture 1404c comprises a protrusion 1416 corresponding to a desired plating gap spacing when the fixture is held in a substrate holder. In the depicted example, maintenance fixture 1404f is a companion fixture for use with maintenance fixture 1404c for performing a gap characterization process on a processing station comprising two electrodeposition cells in which the two substrate holders are coupled to a same mechanical lift.

As mentioned above, a plating gap characterization process may measure a plating gap spacing at multiple angular locations by rotating a substrate holder holding the fixture between each measurement. Thus, accurate knowledge of an angular location of a protrusion 1416 allows for accurate gap characterization at the multiple angular locations. As such, a maintenance fixture storage location may comprise an angular alignment feature configured to align with a corresponding angular alignment feature of a maintenance fixture. This allows a handling system to remove maintenance fixture 1404c with protrusion 1416 in a known angular position. FIG. 14B shows an example alignment feature 1420 for maintenance storage location 1402c. Maintenance fixture 1404c comprises a corresponding alignment feature 1422. In FIG. 14B, corresponding alignment feature 1422 aligns with alignment feature 1420. Thus, maintenance fixture 1404c is positioned correctly within storage location 1402c. As such, presence sensor 1424 detects a presence of the maintenance fixture. In comparison, FIG. 14C depicts an example of misalignment. As shown in the top view of FIG. 14C, corresponding alignment feature 1422 does not align with alignment feature 1420. Thus, maintenance fixture 1404c does not block the light beam and presence sensor 1424 detects an absence of a maintenance fixture at storage location 1402c. In some examples, the robot system may be configured to rotate maintenance fixture 1404c (indicated by the arrows in FIG. 14C) to align alignment feature 1420 with corresponding alignment feature 1422. In other examples, user intervention may be used to align the maintenance fixture with the storage location. In further examples, any other suitable alignment features alternatively or additionally may be used.

As mentioned above, in some examples maintenance fixture storage system 1320 comprises a kinematic mounting system. In the example of FIG. 14, the kinematic mounting system comprises pins 1430 and a bracket 1432. Bracket 1432 is fastened to wall 1326, and may comprise V-shaped grooves (not shown) corresponding to pins 1430. An optional tightening screw may be used to secure maintenance fixture storage system 1320 in place. The kinematic mount takes advantage of normal forces between the pins and grooves to mount maintenance fixture storage system 1320 onto wall 1326 in a precise position. Precise positioning of the maintenance fixture storage system in relation to other components of the substrate processing module may provide for reliable removal/storage of maintenance fixtures via robot system 1322. In other examples, any other suitable mounting system may be used.

Maintenance fixture storage system 1320 further comprises an installation sensor 1434. Installation sensor 1434 is configured to output a signal indicating whether the maintenance fixture storage system is installed within the substrate processing tool. In the depicted example, installation sensor 1434 comprises an optical sensor configured to measure a distance to wall 1426. In other examples, the installation sensor alternatively or additionally may comprise any other suitable sensor, such as a mechanical switch. In some examples, the installation sensor may be located on wall 1426, another surface of substrate processing module 1404, or in any other suitable location.

Returning to FIG. 13, as mentioned above, robot system 1322 is configured to transfer maintenance fixtures between maintenance fixture storage system 1320 and a substrate processing station. In some examples, robot system 1322 is also configured to transfer substrates. In other examples, a maintenance fixture storage and handling system may utilize a dedicated robot system.

Robot system 1322 may comprise any suitable number of robot arms configured to handle substrates and/or maintenance fixtures. In some examples, robot system 1322 may comprise a first arm configured for a first subset of substrate processing stations and a second arm configured for a second subset of substrate processing stations. Further, in some examples, each arm of the robot system is configured for a different electrodeposition cell within a substrate processing station. For example, a first arm may be configured for use with electrodeposition cell 1318A and a second arm for use with electrodeposition cell 1318B. As such, the robot system may be configured to load two ADB fixtures into two electrodeposition cells such that ADB cycles can be performed in parallel. In other examples, the robot system may load an APG characterization fixture and a companion fixture into a pair of electrodeposition cells. In such examples, after performing a gap characterization process the first electrodeposition cell, the robot system may swap the APG characterization fixture and the companion fixture for performing the gap characterization process the second electrodeposition cell.

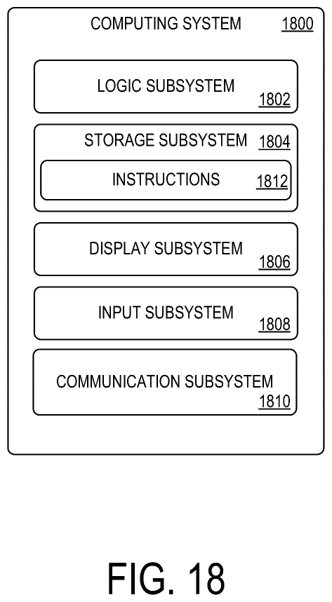

Substrate processing tool 1300 further comprises a controller 1350. Controller 1350 is operatively connected to front-end module 1302 and substrate processing module 1304. Controller 1350 is configured to control operation of front-end robot 106, substrate processing stations 1310, 1312, 1314, 1316, and the maintenance fixture storage and handling system. Controller 1350 may comprise one or more processors. Controller 1350 may further comprise one or more storage devices storing instruction executable by the one or more processors. In some examples, controller 1350 is remote to substrate processing tool 1300 and accessible by computer network. In other examples, controller 1350 is local to substrate processing tool 1300. Controller 1350 may comprise any suitable computing system. Examples computing systems discussed in more detail with regards to FIG. 18.

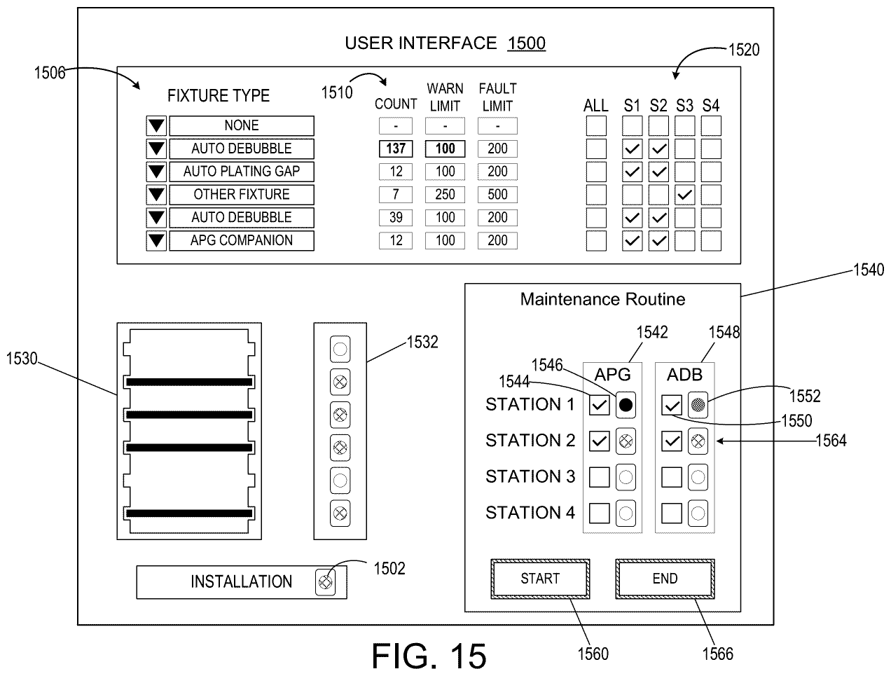

Controller 1350 is further configured to control display 1352. In some examples, display 1352 is incorporated into a processing tool with controller 1350. In other examples, display 1352 is remotely located. Controller 1350 is configured to output information for display on a user interface 1354 of display 1352. User interface 1354 may display status information regarding substrate processing tool 1300. Further, user interface 1354 may allow for a user to control substrate processing tool 1300, including maintenance cycles. Examples of user interface 1354 are discussed below with regards to FIG. 15.

During a maintenance cycle, robot system 1322 removes a maintenance fixture from a maintenance fixture storage location and places the maintenance fixture in a substrate processing station. The substrate processing station is then controlled to perform the maintenance cycle using the maintenance fixture. Afterwards, robot system 1322 removes the maintenance fixture from the substrate processing station and places it in a maintenance fixture storage location of maintenance fixture storage system 1320. In some examples, robot system may transfer the maintenance fixture to a rinse station (e.g., post-processing station 1316) for rinsing prior to placing the maintenance fixture in the maintenance fixture storage system. Rinsing the maintenance fixture may help remove residual chemicals from the maintenance fixture. In some examples, the maintenance fixture is returned to the maintenance fixture storage location from which it was retrieved. In other examples, the maintenance fixture may be stored in a different location.

FIG. 15 shows an example user interface 1500 configured to display information regarding a maintenance fixture storage and handling system of a substrate processing tool. In some examples, user interface 1500 may be presented on an electronic display incorporated into the substrate processing tool. In other examples, the user interface may be presented remotely on a networked computing device. User interface 1500 is an example of user interface 1354.

User interface 1500 comprises various status indicators to convey information regarding a status of a maintenance fixture storage and handling system. A status indicator may present information in any suitable manner, such as by colors, symbols, text, and/or numbers. For example, user interface 1500 comprises an installation status indicator 1502 that indicates the installation status of the maintenance fixture storage system. The installation status may be determined from a signal received by the controller from an installation sensor of the maintenance fixture storage system. In the example depicted in FIG. 15, installation status indicator 1502 is displayed as indicating that the maintenance fixture storage system is installed. When the maintenance fixture storage system is not installed correctly as determined from installation sensor data, the installation status indicator 1502 is displayed to have an appearance indicating the uninstalled state. In some examples, when installation status indicator 1502 indicates that the maintenance fixture storage system is not installed, other features of the user interface may be unavailable. For example, the unavailable features may be displayed as grayed-out, or not displayed.

User interface 1500 further comprises a maintenance fixture type configuration interface 1506. Type configuration interface 1506 displays information regarding a type of maintenance fixture in each of the maintenance fixture storage locations. In some examples, type configuration interface 1506 may allow a user to select which type of maintenance fixture is stored in each maintenance fixture storage location. The maintenance fixture types shown in the depicted example correspond to the maintenance fixtures stored in maintenance fixture storage system 1320. As such, in user interface 1500, the maintenance fixture storage locations correspond to maintenance fixture storage locations 1402a-f. In the example depicted, maintenance fixture storage location 1402a, corresponding to the top row of type configuration interface 1506, does not have an associated maintenance fixture. Thus, the maintenance fixture type is selected as “None”. Continuing, storage location 1402b is associated with an ADB fixture. Storage location 1402c is associated with an APG characterization fixture. Storage location 1402d is associated with a fixture labeled “other”. Storage location 1402e is associated with an ADB fixture. Storage location 1402f is associated with a companion fixture for an APG characterization fixture. In some examples, a user may change the fixture type by selecting a new fixture type from a menu. Further, in some examples, a presence sensor is configured to detect a type of maintenance fixture, which is then displayed in type configuration interface 1506.

User interface 1500 further comprises an interface 1510 for displaying usage counts of the maintenance fixtures. The rows of interface 1510 may correspond to the rows of interface 1506. Thus, the usage count for a particular maintenance fixture storage location is incremented when the corresponding maintenance fixture is used in a maintenance cycle. Interface 1510 may optionally include one or more usage limits, such as a warn limit or a fault limit. Interface 1510 may also display indications and/or output warnings based on a comparison between the usage count and a usage limit for a maintenance fixture. In the depicted example, interface 1510 displays a warn limit. When the usage count for a maintenance fixture meets and/or exceeds the warn limit, user interface 1500 may output a warning notification recommending that the maintenance fixture be replaced. Additionally, or alternatively, user interface 1500 may display an indication that the usage count exceeds the warn limit. For example, the usage count for maintenance fixture 1404b in the second storage location exceeds the warn limit. As such, the usage count box and warn limit box for maintenance fixture 1404b are highlighted, as indicated by bold text in the second row.

Interface 1510 also displays a fault limit. When the usage count meets and/or exceeds the fault limit, user interface 1500 may output a fault notification that the maintenance fixture should no longer be used for performing maintenance cycles. In some examples, the usage count, warn limit, and/or fault limit may be user-adjustable settings. In other examples, the usage count, warn limit and/or fault limit may be fixed settings. In other examples, one or more of the usage count, the warn limit, and/or the fault limit may be omitted from interface 1510.

In some examples, a processing tool may have different stations to perform different processes. In such examples, different maintenance fixtures may be used for the different stations. As such, user interface 1500 further comprises a compatibility interface 1520 for configuring compatibility between one or more maintenance fixtures and one or more substrate processing stations. For example, substrate processing stations 1310, 1312, 1134, and 1316 of substrate processing module 1304 may correspond to columns S1, S2, S3, and S4 of interface 1520. In the example shown, a checked box indicates compatibility between a maintenance fixture (rows) and a substrate processing station (columns). In this example, the maintenance fixture stored in the second storage location—an ADB fixture—is compatible with substrate processing stations 1310 and 1312. This compatibility is indicated by the checked boxes under S1 and S2. In some examples, user interface 1500 may receive a user input modifying the compatibility between a maintenance fixture and a substrate processing station. In response, the user interface displays the updated compatibility.

User interface 1500 further comprises a presence interface 1530 for displaying presence information regarding the presence of maintenance fixtures in the maintenance fixture storage system. Presence interface 1530 shows a simplified representation of maintenance fixture storage system 1320 of FIG. 14A. Here, presence interface 1530 displays a maintenance fixture in each of maintenance fixture storage locations 1402b, 1402c, 1402d, and 1402f. Further, presence indicators 1532 display an indicator for each maintenance fixture storage location to indicate a presence or absence of a fixture in each storage location.

User interface 1500 further comprises a maintenance routine interface 1540. Maintenance routine interface 1540 displays status information regarding a selected maintenance routine. A maintenance routine may comprise one or more maintenance cycles. As described above, example maintenance cycles include a gap characterization process and an ADB cycle. Maintenance routine interface 1540 may allow a user to, for example, configure a maintenance routine, select a substrate processing station for a maintenance cycle, and/or initiate a selected maintenance routine.

In the example of FIG. 15, at 1542, maintenance routine interface 1540 displays information related to performing gap characterization processes using APG characterization fixtures. A gap characterization process may also use an APG companion fixture, where two or more plating cells share a common substrate holder lift. Maintenance routine interface 1540 comprises one or more APG controls 1544. APG controls 1544 allow a user to select substrate processing stations on which to perform a plating gap characterization process. Maintenance routine interface 1540 further comprises one or more APG indicators 1546. Each APG indicator 1546 displays a status indication for the gap characterization process on the selected substrate processing station.

At 1548, maintenance routine interface 1540 displays information related to performing ADB cycles using ADB fixtures. Maintenance routine interface 1540 comprises one or more ADB controls 1550. Each ADB control allows a user to select an associated substrate processing station for an auto debubbling cycle. The selected maintenance routine may be scheduled and/or initiated via a “START” button 1560. The information regarding the selected maintenance routine is received by a controller (e.g., controller 1550) which can then operate the substrate processing tool to perform one or more maintenance cycles. Maintenance routine interface 1540 further comprises one or more ADB indicators 1552. Each indicator 1552 displays a status indication for the gap characterization process on the selected substrate processing station.

APG indicators 1546 and ADB indicators 1552 may indicate a current status in any suitable manner. For example, an indicator may be displayed to appear as illuminated to indicate that a maintenance cycle is scheduled for a particular substrate processing station. In some examples, APG indicators 1546 and ADB indicators 1552 utilize different colors to indicate different statuses of a maintenance cycle on a substrate processing station. Example statuses for a maintenance cycle include scheduled, not scheduled, in progress, completed, error, and abnormal. An abnormal status may indicate, for example, a measurement that is outside an acceptable tolerance range. For example, status indicator 346 may indicating an abnormal status of a gap characterization process for station 1. The abnormal status may correspond to a parallelism and/or a separation distance that is outside an acceptable tolerance.

In some examples, the status of the selected maintenance routine may be displayed in a status indication field of maintenance routine interface 1540. Further, the status of each maintenance cycle may be displayed via APG indicators 1546 and ADB indicators 1552. For example, as shown in FIG. 15, station 1 and station 2 were selected for a gap characterization process and an auto debubbling cycle. As indicated by APG indicator 1546, the gap characterization process on station 1 produced an abnormal result. As indicated by ADB indicator 1552, the auto debubbling cycle is in progress on station 1. Additionally, the gap characterization process and auto debubbling cycle are scheduled for station 2, as indicated at 1564. As such, the overall status for the selected maintenance routine is “in progress”.

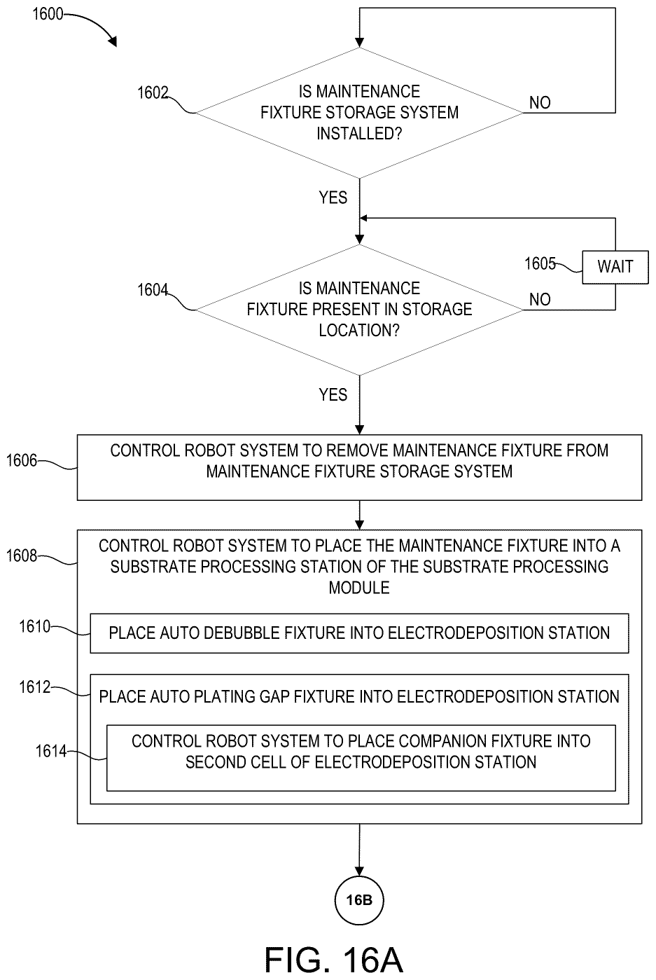

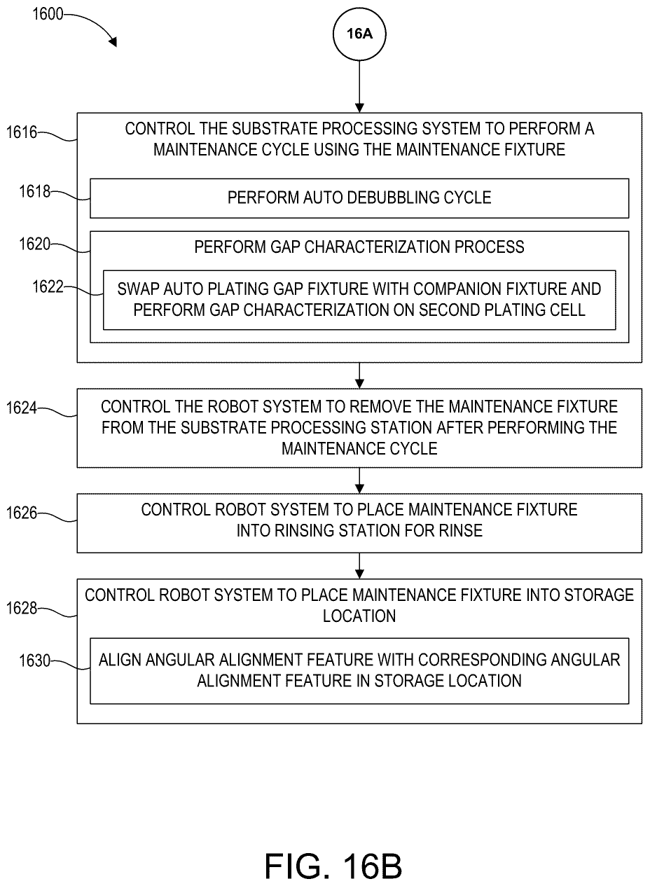

Maintenance routine interface 1540 further comprises an “END” button 1566. “END” button 1566 allows a user to terminate a maintenance cycle and/or maintenance routine in progress. In some examples, maintenance routine interface 1540 may optionally display a time of a previous maintenance routine and/or a time of a scheduled maintenance routine. In some examples, maintenance routine interface 1540 may display other information not shown in FIG. 15. As mentioned above, substrate processing tool 1300 may be controlled to perform a maintenance cycle using a maintenance fixture. FIGS. 16A-16B shows a flow diagram depicting example method 1600 for performing a maintenance cycle within a substrate processing tool. At 1602 of FIG. 16A, the method checks to determine whether the maintenance fixture storage system is installed. If the maintenance fixture storage system is not installed, the method may terminate or return to 1602 to perform another check. Method 1600 may optionally output a notification a user to install the maintenance fixture storage system. If the maintenance fixture storage system is installed, the method may proceed to 1604 and check whether a maintenance fixture is present in the maintenance fixture storage system. In some examples, the check at 1604 comprises checking for a selected type of maintenance fixture. For example, when a gap characterization process is to be performed, 1604 may comprise checking for an APG characterization fixture. Likewise, if an auto debubbling cycle is to be performed, 1604 may comprise checking for an ADB fixture. If the selected maintenance fixture is not present, the method may wait at 1605 until the maintenance fixture is present. If the maintenance fixture is present, the method can proceed to 1606.

At 1606, method 1600 comprises controlling a robot system to remove a maintenance fixture from a maintenance fixture storage system located within a substrate processing module of the substrate processing tool.

Continuing, at 1608, method 1600 comprises controlling the robot system to place the maintenance fixture into a substrate processing station of the substrate processing module. In some examples, at 1610, the method comprises controlling the robot system to place an ADB fixture into an electrodeposition station. Further, in some examples, at 1612, method 1600 comprises controlling the robot system to place an APG characterization fixture into an electrodeposition station.

In some examples, the electrodeposition station may comprise two or more electrodeposition cells. As such, method 1600 may comprise, at 1614, controlling the robot system to place a companion fixture into a second electrodeposition cell. Likewise, 1610 may comprise controlling the robot system to place a first ADB fixture into a first electrodeposition cell and controlling the robot system to place a second ADB fixture into a second electrodeposition cell.

Continuing with FIG. 16B, method 1600 further comprises, at 1616, controlling the substrate processing station to perform a maintenance cycle using the maintenance fixture. In some examples, an ADB cycle is performed at 1618. Further, in some examples, a gap characterization process is performed at 1620. Additionally, where an electrodeposition station comprises two or more cells, the method further may comprise controlling the robot system to swap the APG characterization fixture in a first electrodeposition cell with a companion fixture in a second electrodeposition cell, at 1622. Then, a gap characterization process is performed on the second electrodeposition cell.

Continuing method 1600, at 1624, method 1600 may further comprise controlling the robot system to remove the maintenance fixture from the substrate processing station after performing the maintenance cycle. In some examples, method 1600 further comprises, at 1626, controlling the robot system to place the maintenance fixture into a rinsing station, and controlling the rinsing station to rinse the maintenance fixture. Rinsing may help prevent corrosion of maintenance fixtures and cross-contamination between substrate processing stations. After removing the maintenance fixture from the substrate processing station and optionally rinsing the maintenance fixture, method 1600 further comprises controlling the robot system to place the maintenance fixture into the maintenance fixture storage location of the maintenance fixture storage system, at 1628. In some examples, at 1630, the method comprises controlling the robot system to place the maintenance fixture into the maintenance fixture storage location with an angular alignment feature aligned with a corresponding angular alignment feature of the maintenance fixture storage system. Incorrect alignment may be corrected by user intervention in some examples, whereas the robot may rotate the maintenance fixture in other examples.

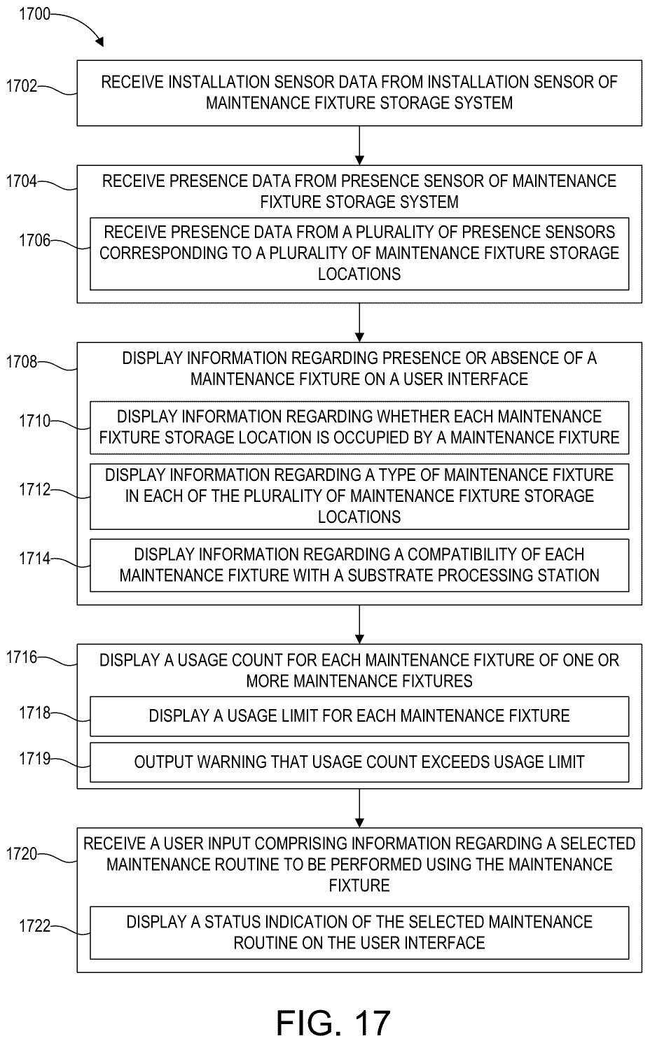

FIG. 17 shows an example method 1700 for displaying information regarding a maintenance fixture storage system on a user interface. At 1702, the method comprises receiving installation sensor data comprising a signal indicating whether the maintenance fixture storage system is installed in the substrate processing tool. Method 1700 further comprises, at 1704, receiving presence data from one or more sensors of the maintenance fixture storage and handling system. As discussed above, each presence sensor is configured to output a signal indicative of whether a maintenance fixture is positioned within a maintenance fixture storage location of the maintenance fixture storage and handling system. In some examples, at 1706, the method comprises receiving presence data from a plurality of presence sensors corresponding to a plurality of maintenance fixture storage locations within the maintenance fixture storage system. At 1708, the method further comprises displaying information on a presence or absence of the maintenance fixture on the user interface. In some examples, the maintenance fixture storage and handling system comprises a plurality of maintenance fixture storage locations. In such examples, method 1700 comprises, at 1710, displaying information regarding whether each maintenance fixture storage location is occupied by a maintenance fixture.

In some examples, at 1712, the method may further comprise displaying, on the user interface, information regarding a type of maintenance fixture in each of the plurality of maintenance fixture storage locations. Example user interface features for displaying such information are described above with regards to FIG. 15. Further, at 1714, method 1700 may comprise displaying information regarding a compatibility of each maintenance fixture with a substrate processing station.

In some examples, additional information regarding a maintenance fixture is displayed on the user interface. For example, at 1716, method 1700 may comprise displaying a usage count for the maintenance fixture on the user interface. In some examples, method 1700 further comprises displaying a usage limit (e.g., warn limit or fault limit) for each maintenance fixture, at 1718. Additionally, in some examples, at 1719, the method comprises outputting a warning that a usage count exceeds a usage limit for a maintenance fixture.

Continuing, in some examples, at 1720, method 1700 further comprises receiving a user input comprising information regarding a selected maintenance routine to be performed using the maintenance fixture. Furthermore, at 1722, method 1700 comprises displaying a status indication of the selected maintenance routine on the user interface.

Thus, by utilizing a maintenance fixture storage system as disclosed, maintenance cycles can be performed within a substrate processing tool with less downtime. Further, the disclosed examples may help to avoid exposure of processing chemistries to maintenance personnel. While V disclosed in the context of an electrodeposition tool, a maintenance fixture storage and handling system according to the present disclosure can be utilized with any other suitable type of processing tool.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 18 schematically shows a non-limiting embodiment of a computing system 1800 that can enact one or more of the methods and processes described above. Computing system 1800 is shown in simplified form. Computing system 1800 may take the form of one or more personal computers, workstations, computers integrated with wafer processing tools, and/or network accessible server computers.

Computing system 1800 includes a logic subsystem 1802 and a storage subsystem 1804. Computing system 1800 may optionally include a display subsystem 1806, input subsystem 1808, communication subsystem 1810, and/or other components not shown in FIG. 18. Computing system 130, remote computing system 140, and controller 1350 are examples of computing system 1800.

Logic subsystem 1802 includes one or more physical devices configured to execute instructions. For example, logic subsystem 1802 may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

Logic subsystem 1802 may include one or more processors configured to execute software instructions. Additionally or alternatively, logic subsystem 1802 may include one or more hardware or firmware logic subsystems configured to execute hardware or firmware instructions. Processors of logic subsystem 1802 may be single-core or multi-core, and the instructions executed thereon may be configured for sequential, parallel, and/or distributed processing. Individual components of logic subsystem 1802 optionally may be distributed among two or more separate devices, which may be remotely located and/or configured for coordinated processing. Aspects of logic subsystem 1802 may be virtualized and executed by remotely accessible, networked computing devices configured in a cloud-computing configuration.

Storage subsystem 1804 includes one or more physical devices configured to hold instructions 1812 executable by the logic subsystem to implement the methods and processes described herein. When such methods and processes are implemented, the state of storage subsystem 1804 may be transformed—e.g., to hold different data.

Storage subsystem 1804 may include removable and/or built-in devices. Storage subsystem 1804 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage subsystem 1804 may include volatile, nonvolatile, dynamic, static, read/write, read-only, random-access, sequential-access, location-addressable, file-addressable, and/or content-addressable devices.

It will be appreciated that storage subsystem 1804 includes one or more physical devices. However, aspects of the instructions described herein alternatively may be propagated by a communication medium (e.g., an electromagnetic signal, an optical signal, etc.) that is not held by a physical device for a finite duration.

Aspects of logic subsystem 1802 and storage subsystem 1804 may be integrated together into one or more hardware-logic components. Such hardware-logic components may include field-programmable gate arrays (FPGAs), program-and application-specific integrated circuits (PASIC/ASICs), program-and application-specific standard products (PSSP/ASSPs), system-on-a-chip (SOC), and complex programmable logic devices (CPLDs), for example.

When included, display subsystem 1806 may be used to present a visual representation of data held by storage subsystem 1804. This visual representation may take the form of a graphical user interface (GUI). As the herein described methods and processes change the data held by the storage subsystem, and thus transform the state of the storage subsystem, the state of display subsystem 1806 may likewise be transformed to visually represent changes in the underlying data. Display subsystem 1806 may include one or more display devices utilizing virtually any type of technology. Such display devices may be combined with logic subsystem 1802 and/or storage subsystem 1804 in a shared enclosure, or such display devices may be peripheral display devices.

When included, input subsystem 1808 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on-or off-board. Example NUI componentry may include a microphone for speech and/or voice recognition, and an infrared, color, stereoscopic, and/or depth camera for machine vision and/or gesture recognition.

When included, communication subsystem 1810 may be configured to communicatively couple computing system 1800 with one or more other computing devices. Communication subsystem 1810 may include wired and/or wireless communication devices compatible with one or more different communication protocols. As non-limiting examples, the communication subsystem may be configured for communication via a wireless telephone network, or a wired or wireless local-or wide-area network. In some embodiments, the communication subsystem may allow computing system 1800 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A fixture for characterizing a spacing of a plating gap of an electrodeposition tool, the plating gap comprising a distance between a substrate surface and an anode structure of the electrodeposition tool during electrodeposition, the fixture comprising:
a substrate holder interface configured to contact a seal of a substrate holder of the electrodeposition tool; and
a protrusion comprising a contact surface configured to contact the anode structure of the electrodeposition tool during a plating gap characterization process, wherein a thickness dimension comprising a distance between a plane of the substrate holder interface and the contact surface of the protrusion corresponds to a preselected plating gap spacing.

2. The fixture of claim 1, wherein the fixture is formed at least in part from a polymer.

3. The fixture of claim 1, wherein the fixture is formed at least in part from a metal.

4. The fixture of claim 1, wherein the protrusion comprises a curvature comprising a radius within a range of 0.5 inch and 1.5 inch.

5. The fixture of claim 1, wherein the protrusion is offset from a rotational center of the fixture.

6. The fixture of claim 5, wherein a center of mass of the fixture is located at the rotational center of the fixture.

7. The fixture of claim 1, wherein the substrate holder interface comprises a thinner profile than an adjacent region of the fixture.

8. The fixture of claim 1, further comprising one or more angular alignment features.

9. An electrodeposition system, comprising:
a plating cell comprising an anode structure;
a substrate holder;
a lift configured to change a spacing between the anode structure and the substrate holder;
a motor configured to rotate the substrate holder; and
a controller configured to characterize a plating gap of the electrodeposition system, the controller comprising instructions executable to
actuate the lift to move the substrate holder relative to the anode structure while a gap characterization fixture is held in the substrate holder,
apply a rotational torque to the substrate holder,
detect a lift position at which the substrate holder meets a threshold rotational condition due to interaction between the anode structure and the gap characterization fixture, and
output a gap characterization measurement based upon the lift position at which the substrate holder met the threshold rotational condition.

10. The electrodeposition system of claim 9, wherein the controller comprises instructions executable to output the gap characterization measurement for each of a plurality of rotation angles of the substrate holder.

11. The electrodeposition system of claim 9, wherein the controller is executable to detect the lift position at which the substrate holder meets the threshold rotational condition by actuating the lift to move the substrate holder toward the anode structure until a hard touch is detected between the anode structure and the gap characterization fixture held in the substrate holder, and while the rotational torque is applied, actuate the lift to move the substrate holder away from the anode structure.

12. The electrodeposition system of claim 11, wherein the instructions are further executable to detect the hard touch by detecting a threshold torque applied by the lift.

13. The electrodeposition system of claim 11, wherein the plating cell is located in a substrate processing station, and further comprising
a maintenance fixture storage system configured to hold one or more maintenance fixtures, and
a robot system controllable by the controller to transfer a maintenance fixture from the maintenance fixture storage system to the substrate processing station.

14. The electrodeposition system of claim 13, wherein the maintenance fixture storage system comprises one or more maintenance fixture storage locations and one or more presence sensors each configured to detect a presence of a maintenance fixture stored in a respective fixture storage location, and wherein the controller is configured to receive presence data from the one or more presence sensors of the maintenance fixture storage system, and display information on a presence or absence of the maintenance fixture on a user interface displayed on a display device.

15. An electrodeposition system, comprising:
a plating cell comprising an anode structure;
a substrate holder;
a lift configured to change a spacing between the plating cell and the substrate holder;
a display; and
a computing device comprising a logic subsystem and a storage subsystem, the storage subsystem comprising instructions executable by the logic subsystem to
actuate the lift to move the substrate holder toward the anode structure until a hard touch between the anode structure and a gap characterization fixture in the substrate holder is detected,
apply a rotational torque to the substrate holder,
while the rotational torque is applied, actuate the lift to move the substrate holder away from the anode structure,
detect a lift position at which the substrate holder begins to rotate,
output a gap characterization measurement based upon the lift position at which the substrate holder began to rotate, and
display the gap characterization measurement on a user interface via the display.

16. The electrodeposition system of claim 15, wherein the instructions are executable to output the gap characterization measurement for each of a plurality of rotation angles of the substrate holder, and display on the user interface a cell parallelism measurement characterizing an alignment of the plating cell to the substrate holder.

17. The electrodeposition system of claim 16, wherein the instructions are executable to receive a user input of a cell parallelism threshold, compare the cell parallelism measurement to the cell parallelism threshold, and output a notification if the cell parallelism measurement exceeds the cell parallelism threshold.

18. The electrodeposition system of claim 17, wherein the instructions are executable to display a representation of an adjustment to be made to one or more leveling adjusters based on each gap characterization measurement.

19. The electrodeposition system of claim 16, wherein the instructions are executable to automatically adjust one or more leveling adjusters based on each gap characterization measurement.

20. The electrodeposition system of claim 15, wherein the instructions are executable to display on the user interface, for a plurality of gap characterization measurements each made at a corresponding rotation angle of the substrate holder, one or more of an average gap measurement, a minimum gap measurement, or a maximum gap measurement.
